(19) United States
(12) Patent Application Publication
(10) Pub. No.: US 2019/0296040 A1
(43) Pub. Date: Sep. 26, 2019

(54) SEMICONDUCTOR MEMORY

(71) Applicant: TOSHIBA MEMORY CORPORATION, Minato-ku (JP)

(72) Inventors: Kotaro FUJII, Yokkaichi (JP); Masahisa SONODA, Yokkaichi (JP); Masaru KITO, Kuwana (JP); Satoshi NAGASHIMA, Yokkaichi (JP); Shigeki KOBAYASHI, Kuwana (JP)

(73) Assignee: TOSHIBA MEMORY CORPORATION, Minato-ku (JP)

(21) Appl. No.: 16/122,258

(22) Filed: Sep. 5, 2018

(30) Foreign Application Priority Data
Mar. 22, 2018 (JP) 2018-054147

(51) Int. Cl. H01L 27/11582; H01L 27/11565; H01L 27/1157; G11C 16/04; G11C 16/14; G11C 16/08

(52) U.S. Cl. CPC H01L 27/11582; H01L 27/11565; G11C 16/08; G11C 16/0483; G11C 16/14; H01L 27/1157

(57) ABSTRACT

A semiconductor device according to an embodiment includes first conductors, first pillars, a pillar column. Each of the first pillars is provided through the first conductors. The pillar column includes second pillars that are aligned in a first direction. Each of the second pillars is provided through the first conductors. The pillar column includes first and second columns of the second pillars. The first and second columns of the second pillars are aligned in a second direction that intersects the first direction. The first pillars are arranged on both sides in the second direction of each pillar column. The first conductors are provided continuously on both sides in the second direction of the second pillars that are included in each pillar column.

### CROSS-REFERENCE TO RELATED APPLICATIONS

This application is based upon and claims the benefit of priority from Japanese Patent Application No. 2018-054147, filed Mar. 22, 2018, the entire contents of which are incorporated herein by reference.

### FIELD

Embodiments relate to a semiconductor memory.

### BACKGROUND

A NAND type flash memory in which memory cells are stacked three-dimensionally is known.

### BRIEF DESCRIPTION OF THE DRAWINGS

FIG. 1 is a block diagram showing a configuration example of a semiconductor memory according to a first embodiment.

FIG. 2 is a circuit diagram showing an example of a circuit configuration of a memory cell array that is included in the semiconductor memory according to the first embodiment.

FIG. 3 is a threshold distribution diagram showing an example of a distribution of a threshold voltage of a memory cell transistor.

FIG. 4 is a plan view showing an example of a plan layout of a source line provided in the memory cell array included in the semiconductor memory according to the first embodiment.

FIG. 5 is a plan view showing an example of a plan layout of a selection gate line provided in the memory cell array included in the semiconductor memory according to the first embodiment.

FIG. 6 is a plan view showing an example of a plan layout of a word line provided in the memory cell array included in the semiconductor memory according to the first embodiment.

FIG. 7 is a plan view showing an example of a plan layout of a selection gate line provided in the memory cell array included in the semiconductor memory according to the first embodiment.

FIG. 8 is a plan view showing an example of a plan layout in a memory region of the memory cell array that is included in the semiconductor memory according to the first embodiment.

FIG. 9 is a plan view showing an example of a detailed plan layout in the memory region of the memory cell array that is included in the semiconductor memory according to the first embodiment.

FIG. 10 is a cross-sectional view showing an example of a cross-sectional structure in the memory region of the memory cell array that is included in the semiconductor memory according to the first embodiment.

FIG. 11 is a cross-sectional view showing an example of a cross-sectional structure of a memory pillar provided in the memory cell array that is included in the semiconductor memory according to the first embodiment.

FIG. 12 is a cross-sectional view showing an example of a cross-sectional structure of a replacement pillar provided in the memory cell array that is included in the semiconductor memory according to the first embodiment.

FIG. 13 is a cross-sectional view showing an example of a cross-sectional structure in a hookup region of the memory cell array that is included in the semiconductor memory according to the first embodiment.

FIG. 14 is a circuit diagram showing an example of a circuit configuration of a driver module and a row decoder module that are included in the semiconductor memory according to the first embodiment.

FIG. 15 is a circuit diagram showing an example of a circuit configuration of a sense amplifier module that is included in the semiconductor memory according to the first embodiment.

FIG. 16 is a circuit diagram showing an example of a detailed circuit configuration of the sense amplifier module that is included in the semiconductor memory according to the first embodiment.

FIG. 17, FIG. 18, and FIG. 19 are cross-sectional views in the memory region of the memory cell array, which show an example of a manufacturing process of the semiconductor memory according to the first embodiment.

FIG. 20 is a plan layout view in the memory region of the memory cell array, which shows an example of the manufacturing process of the semiconductor memory according to the first embodiment.

FIG. 21, FIG. 22, and FIG. 23 are cross-sectional views in the memory region of the memory cell array, which show an example of the manufacturing process of the semiconductor memory according to the first embodiment.

FIG. 24 is a plan layout view in the memory region of the memory cell array, which shows an example of the manufacturing process of the semiconductor memory according to the first embodiment.

FIG. 25, FIG. 26, FIG. 27, FIG. 28, FIG. 29, and FIG. 30 are cross-sectional views in the memory region of the memory cell array, which show an example of the manufacturing process of the semiconductor memory according to the first embodiment.

FIG. 31 is a timing chart showing an example of a read operation in the semiconductor memory according to the first embodiment.

FIG. 32 is a timing chart showing an example of a write operation in the semiconductor memory according to the first embodiment.

FIG. 33 is a timing chart showing an example of an erase operation in the semiconductor memory according to the first embodiment.

FIG. 34 is a plan view showing an example of a plan layout in a memory region of a memory cell array in a first modified example of the first embodiment.

FIG. 35 is a plan view showing an example of a plan layout in a memory region of a memory cell array in a second modified example of the first embodiment.

FIG. 36 is a plan view showing an example of a plan layout in a memory region of a memory cell array in a third modified example of the first embodiment.

FIG. 37 is a plan view showing an example of a plan layout in a memory region of a memory cell array in a fourth modified example of the first embodiment.

FIG. 38 is a plan view showing an example of a plan layout in a memory region of a memory cell array in a fifth modified example of the first embodiment.

FIG. 39 is a plan view showing an example of a plan layout in a memory region of a memory cell array that is included in a semiconductor memory according to a second embodiment.

FIG. 40 is a plan view showing an example of a detailed plan layout in the memory region of the memory cell array that is included in the semiconductor memory according to the second embodiment.

FIG. 41 is a plan view showing an example of a plan layout in a memory region of a memory cell array in a first modified example of the second embodiment.

FIG. 42 is a plan view showing an example of a plan layout in a memory region of a memory cell array in a second modified example of the second embodiment.

FIG. 43 is a plan view showing an example of a plan layout in a memory region of a memory cell array in a third modified example of the second embodiment.

FIG. 44 is a plan view showing an example of a plan layout in a memory region of a memory cell array in a fourth modified example of the second embodiment.

FIG. 45 is a plan view showing an example of a plan layout in a memory region of a memory cell array that is included in a semiconductor memory according to a third embodiment.

### DETAILED DESCRIPTION

A semiconductor memory according to an embodiment includes first conductors, first pillars, a pillar column. The first conductors are stacked via an insulator. Each of the first pillars is provided through the first conductors. Each of the first pillars includes a portion intersecting one of the first conductors and functioning as a memory cell. The pillar column includes second pillars that are aligned in a first direction. Each of the second pillars is provided through the first conductors and does not include a portion functioning as the memory cell. The pillar column includes a first column of the second pillars and a second column of the second pillars. The first column of the second pillars and the second column of the second pillars are aligned in a second direction that intersects the first direction. The first pillars are arranged on both sides in the second direction of each of the first column and the second column. The first conductors are provided continuously on both sides in the second direction of the second pillars that are included in each of the first column and the second column. The first conductors are provided continuously in the second direction between the first column of the second pillars and the second column of the second pillars.

Hereinafter, the embodiment will be explained with reference to the accompanying drawings. The embodiment exemplifies an apparatus and a method to embody a technical idea of an invention. The drawings are schematic or conceptual, and the dimensions and ratios, etc. of each drawing are not necessarily the same as those of the actual implementation. Furthermore, the technical idea of the present invention is not identified by a shape, a structure, and an arrangement, etc. of a constituent element. In the explanation below, constituent elements having the same functions and configurations will be denoted by the same reference symbols.

### First Embodiment

A semiconductor memory 1 according to a first embodiment will be explained in the following.

[1-1] Configuration of Semiconductor Memory 1

[1-1-1] Entire Configuration of Semiconductor Memory 1

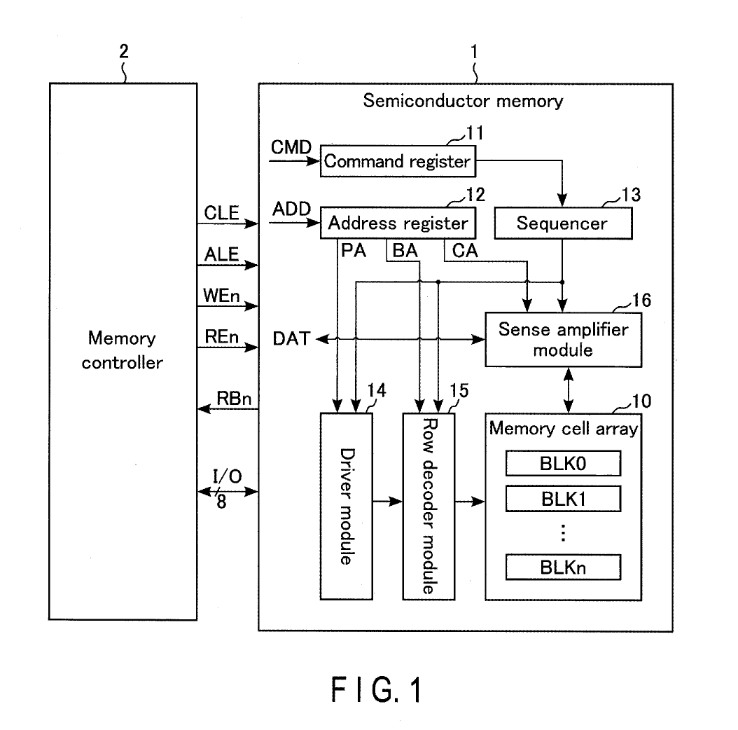

The semiconductor memory 1 is a NAND-type flash memory that is controlled by an external memory controller 2, and is capable of storing data in a non-volatile manner. FIG. 1 shows a configuration example of the semiconductor memory 1 according to the first embodiment.

As shown in FIG. 1, the semiconductor memory 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or greater than 1). A plurality of source lines, a plurality of bit lines, and a plurality of word lines are provided on the memory cell array 10.

A block BLK is a set of non-volatile memory cells, and is, for example, used as a unit to erase data. Each of a plurality of blocks BLK is associated with a plurality of source lines. Each memory cell is associated with one bit line and one word line. The configuration of the memory cell array 10 will be described later in detail.

The command register 11 holds a command CMD that is received by the semiconductor memory 1 from the memory controller 2. The command CMD includes, for example, commands to cause the sequencer 13 to execute a read operation, a write operation, and an erase operation.

The address register 12 holds address information ADD that the semiconductor memory 1 receives from the memory controller 2. The address information ADD includes, for example, a block address BA, a page address PA, and a column address CA.

The block address BA is used, for example, to select a block BLK that includes a memory cell that is a target for various types of operations. The page address PA is used, for example, to select a word line that is associated with a memory cell that is a target for various types of operations. The column address CA is used, for example, to select a bit line that is a target for various types of operations.

The sequencer 13 controls the operation of the entire semiconductor memory 1 based on the command CMD held in the command register 11. For example, the sequencer 13 controls the driver module 14, the row decoder module 15, and the sense amplifier module 16. The sequencer 13 also executes a read operation of data DAT that is stored in the memory cell array 10, a write operation of the data DAT that is received from the memory controller 2, and an erase operation of data that is stored in the memory cell array 10, etc.

Based on the control performed by the sequencer 13, the driver module 14 generates a voltage that is to be used for the read operation, the write operation, and the erase operation, etc. For example, the driver module 14 generates a voltage that corresponds to each of the selected word line, the non-selected word line, the selected source line, and the non-selected source line. The driver module 14 applies the generated voltage to a corresponding signal line based on the page address PA held in the address register 12 and the control performed by the sequencer 13.

The row decoder module 15 selects one block BLK based on the block address BA held in the address register 12. The row decoder module 15 transfers the voltage applied to the corresponding signal line among voltages applied to various signal lines by the driver module 14 to, for example, each source line provided to the selected block BLK (selected source line) and source line provided to a non-selected block BLK (non-selected source line). In the above manner, in the semiconductor memory 1, a source line is used to select the block BLK.

The sense amplifier module 16 applies a desired voltage to each bit line in accordance with write data DAT received by the semiconductor memory 1 from the memory controller 2. The sense amplifier module 16 determines data stored in a memory cell based on the voltage of the bit line, and transmits the determined read data DAT to the memory controller 2.

Communication between the semiconductor memory 1 and the memory controller 2 supports, for example, a NAND interface standard. For example, in communications between the semiconductor memory 1 and the memory controller 2, a command latch enable signal CLE, an address latch enable signal ALE, a write enable signal Wen, a read enable signal REn, a ready/busy signal RBn, and an input-output signal I/O are used.

The command latch enable signal CLE is a signal indicating that the input-output signal I/O received by the semiconductor memory 1 is a command CMD. The address latch enable signal ALE is a signal indicating that the input-output signal I/O received by the semiconductor memory 1 is address information ADD. The write enable signal WEn is a signal instructing the semiconductor memory 1 to input the input-output signal I/O. The read enable signal REn is a signal instructing the semiconductor memory 1 to output the input-output signal I/O.

The ready/busy signal RBn is a signal for notifying the memory controller 2 of whether the semiconductor memory 1 is in a ready state in which a command from the controller 2 can be received, or in a busy state in which a command from the controller 2 cannot be received. The input-output signal I/O is, for example, an 8-bit signal, and may include a command CMD, address information ADD, and data DAT.

The semiconductor memory 1 and the memory controller 2 explained above may constitute a semiconductor device by a combination thereof. Such a semiconductor device may be, for example, a memory card, such as an SDTM card, and a solid state drive (SSD).

[1-1-2] Configuration of Memory Cell Array 10

(Circuit Configuration of Memory Cell Array 10)

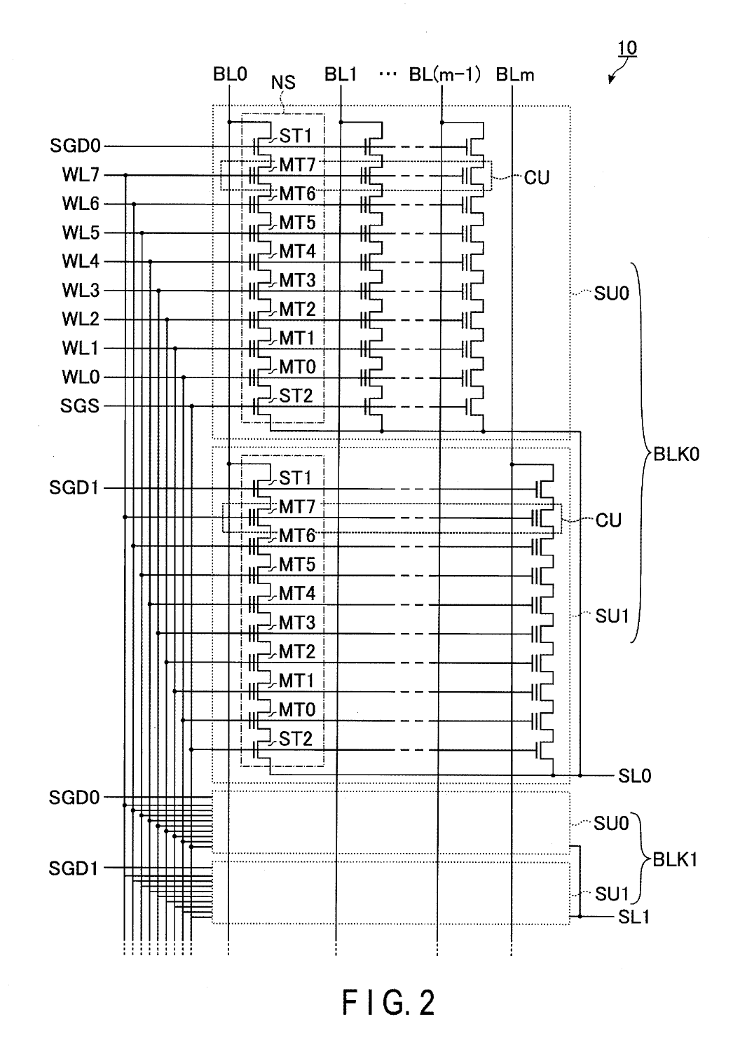

FIG. 2 shows an example of a circuit configuration of the memory cell array 10 in the first embodiment, and shows a block BLK extracted from among a plurality of blocks BLK included in the memory cell array 10.

In the following explanation, the memory cell array 10 is provided with m bit lines BL0 to BLm (m is an integer that is equal to or greater than 1) and n source lines SL0 to SLn, respectively.

As shown in FIG. 2, the block BLK includes, for example, two string units SU0 and SU1. Each of the string units SU includes a plurality of NAND strings NS. Each of the NAND strings NS includes, for example, memory cell transistors MT0 to MT7 and selection transistors ST1 and ST2.

Each memory cell transistor MT includes a control gate and a charge storage layer, and stores data in a nonvolatile manner. In each NAND string NS, the memory cell transistors MT0 to MT7 are connected in series between the source of the selection transistor ST1 and the drain of the selection transistor ST2.

In the block BLK0, each control gate of the plurality of memory cell transistors MT0 to MT7 within the string unit SU0 is commonly connected to each word line WL0 to WL7. In the same manner, in block BLK0, each control gate of the plurality of memory cell transistors MT0 to MT7 within the string unit SU1 is commonly connected to each word line WL0 to WL7.

In this manner, the word lines WL0 to WL7 in the block .BLK0 are shared between the string units SU0 and SU1. Furthermore, in the first embodiment, each of the word lines WL0 to WL7 is shared among the blocks BLK0 to BLKn.

Each of the selection transistors ST1 and ST2 is, for example, used to select a string unit SU in the read operation and the write operation, etc. The drains of a plurality of selection transistors ST1 within the NAND strings NS included in each of the string units SU are respectively connected to different bit lines BL.

In the first embodiment, the number of NAND strings NS included in each of the string units SU is designed to be fewer than the number of bit lines BL. Therefore, in the case of focusing on one string unit SU, the bit lines BL that are not connected to the plurality of selection transistors ST1 within such string unit SU will be included in the m bit lines BL. In each string unit SU, the bit lines BL that are not connected to the plurality of selection transistors ST1 within the string unit SU may be different for each string unit SU.

For example, when focusing on the block BLK0 shown in FIG. 2, the selection transistors ST1 within the string units SU0 and SU1 are connected to the bit line BL0, the selection transistor ST1 within the string unit SU0 is connected to a bit line BL(m-1), and the selection transistor ST1 within the string unit SU1 is connected to a bit line BLm.

In the above manner, the bit line BL connected to two selection transistors ST1 within the block BLK0 and the bit line BL connected to one selection transistor ST1 within the block BLK0 are included in the m bit lines BL. In other words, the m bit lines BL include bit lines BL that are connected to different numbers of selection transistors ST1 (that is, NAND strings NS).

In each string unit SU, the bit lines BL that are not connected to the plurality of selection transistors ST1 within the string unit SU may be different for each block BLK. Furthermore, depending on the design of the memory cell array 10, a dummy bit line that is not connected to the selection transistor ST1 may also be included in them bit lines BL.

In block BLK0, a selection gate line SGD0 is commonly connected to the gates of a plurality of selection transistors ST1 within the string unit SU0, and a selection gate line SGD1 is commonly connected to the gates of a plurality of selection transistors ST1 within the string unit SU1. The selection gate lines SGD0 and SGD1 are provided for each block BLK.

In the block BLK0, a selection gate line SGS is commonly connected to the gates of a plurality of selection transistors ST2 within the string unit SU0 and the gates of a plurality of selection transistors ST2 within the string unit SU1. The selection gate line SGS is shared among blocks BLK0 to BLKn.

In the block BLK0, a source line SL0 is commonly connected to the sources of a plurality of selection transistors ST2 within the string unit SU0, and sources of a plurality of selection transistors ST2 within the string unit SU1. A source line SL is provided for each block BLK. Specifically, the source lines SL1 to SLn are commonly connected to sources of a plurality of selection transistors ST2 included in each of the blocks BLK1 to BLKn.

A group of a plurality of memory cell transistors MT connected to a common word line WL within one string unit SU explained above is referred to as, for example, a cell unit CU.

For example, in the case where each of the memory cell transistors MT stores one bit data, one cell unit CU can store one-page data. In the case where each memory cell transistor MT stores two bit data, one cell unit CU can store two-page data.

Therefore, “one-page data” is defined by a total amount of data stored in a cell unit CU in the case where, for example, each of the memory cell transistors MT included in one cell unit CU stored one bit data.

(Threshold Distribution of Memory Cell Transistors MT and Data Allocation)

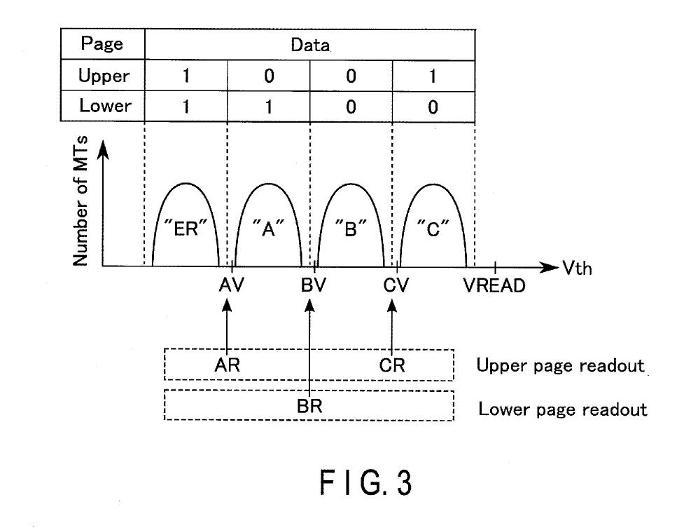

FIG. 3 shows, in the case where one cell unit CU stores two-page data, that is, in the case where each memory cell transistor MT stores two bit data, each example of the threshold distribution of the memory cell transistor MT, data allocation, a read voltage, and a verify voltage. In the graph shown in FIG. 3, a vertical axis corresponds to the number of memory cell transistors MT, and the horizontal axis corresponds to a threshold voltage Vth of the memory cell transistor MT.

As shown in FIG. 3, in the case where each of the memory cell transistors MT stores two bit data, the threshold distribution of the memory cell transistors MT will be divided into four. These threshold distributions will be referred to as, for example, an “ER” level, an “A” level, a “B” level, and a “C” level, in the order starting from a lower distribution voltage. Each of these threshold distributions is allocated, for example, the following two bit data.

“ER” level: “11 (upper bit/lower bit)” data

“A” level: “01” data

“B” level: “00” data

“C” level: “10” data

A read voltage used for each read operation is set between the neighboring threshold distributions. Specifically, a read voltage AR is set between the “ER” level and the “A” level, a read voltage BR is set between the “A” level and the “B” level, and a read voltage CR is set between the “B” level and the “C” level.

More specifically, the read voltage AR is set between a maximum threshold voltage in the “ER” level and a minimum threshold voltage in the “A” level. When the read voltage AR is applied to the gate, the memory cell transistor MT comes to be in an ON-state in the case where the threshold voltage is distributed in the “ER” level, and comes to be in an OFF-state in the case where the threshold voltage is distributed in the “A” level or a higher level.

The read voltage BR is set between a maximum threshold voltage in the “A” level and a minimum threshold voltage in the “B” level. When the read voltage BR is applied to the gate, the memory cell transistor MT comes to be in an ON-state in the case where the threshold voltage is distributed in the “A” level or a lower level, and comes to be in an OFF-state in the case where the threshold voltage is distributed in the “B” level or a higher level.

A read voltage CR is set between a maximum threshold voltage in the “B” level and a minimum threshold voltage in the “C” level. When the read voltage CR is applied to the gate, the memory cell transistor MT comes to be in an ON-state in the case where the threshold voltage is distributed in the “B” level or a lower level, and comes to be in an OFF-state in the case where the threshold voltage is distributed in the “C” level.

A read pass voltage VREAD is set for a voltage higher than the highest threshold distribution. Specifically, the read pass voltage VREAD is set to a voltage higher than the maximum threshold voltage in the “C” level. When the read pass voltage VREAD is applied to the gate, the memory cell transistor MT comes to be in an ON-state regardless of the data to be stored.

Furthermore, a verify voltage used for each write operation is set between the neighboring threshold distributions. Specifically, each of verify voltages AV, BV, and CV is set corresponding to the “A” level, the “B” level, and the “C” level.

Specifically, the verify voltage AV is set between a maximum threshold voltage in the “ER” level and a minimum threshold voltage in the “A” level, and near the “A” level. The verify voltage BV is set between a maximum threshold voltage in the “A” level and a minimum threshold voltage in the “B” level, and near the “B” level. The verify voltage CV is set between a maximum threshold voltage in the “B” level and a minimum threshold voltage in the “C” level, and near the “C” level. In other words, for example, each of the verify voltages AV, BV, and CV is set to a voltage that is higher than the read voltages AR, BR, and CR.

In the write operation, when a threshold voltage of a memory cell transistor MT that is to store certain data is sensed as exceeding a verify voltage corresponding to the data, the semiconductor memory 1 ends a program of the memory cell transistor MT.

In the case where the data allocation explained above is applied, one-page data configured by a lower bit (lower page data) is determined by a read result using the read voltage BR. One-page data configured by an upper bit (upper page data) is determined by a read result using each of the read voltages AR and CR.

In the above manner, since the lower page data and the upper page data are respectively determined by performing reading once and twice, the data allocation shown in FIG. 3 is referred to as, for example, a “1-2 code”. In the first embodiment, an example in the case of adopting the “1-2 code” for the data allocation of the memory cell transistor MT will be explained.

(Plan Layout of Memory Cell Array 10)

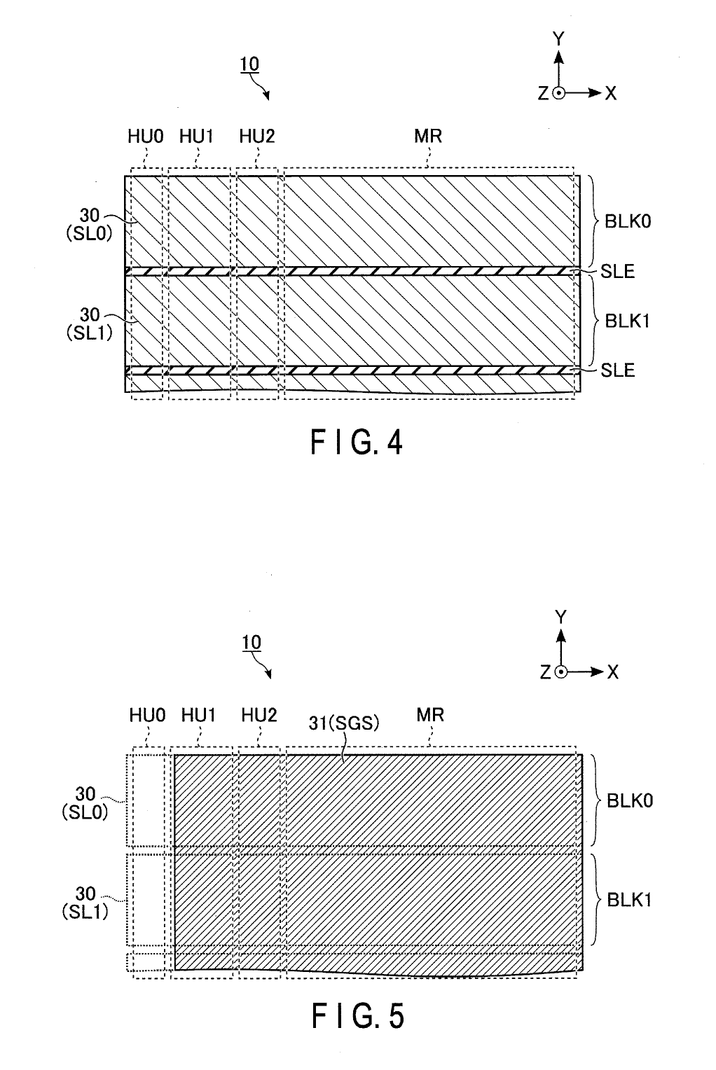

Each of FIG. 4 to FIG 7 shows an example of a plan layout of the memory cell array 10, and shows two blocks BLK0 and BLK1 extracted from a plurality of blocks BLK included in the memory cell array 10. Each of FIG. 4 to FIG. 7 corresponds to a plan layout of a source line SL, a selection gate line SGS, a single word line WL, and a selection gate line SGD.

In the drawings referred to in the following explanation, an X-axis corresponds to an extending direction of the source line SL, a Y-axis corresponds to an extending direction of the bit line BL, and a Z-axis corresponds to a vertical direction with respect to a surface of a semiconductor substrate 20 on which the semiconductor memory 1 is formed.

Furthermore, in the plan view referred to in the following explanation, a hatching is applied to each constituent element as appropriate so that the drawing is easily viewed. The hatching applied to the plan view is not necessarily related to the fabric or characteristic of the constituent element to which the hatching is applied.

As shown in FIG. 4 to FIG. 7, a region on which the memory cell array 10 is formed may be divided into, for example, a memory region MR and hookup regions HU0, HU1, and HU2. The memory region MR is a region that, in essence, holds data. Each of the hookup regions HU0, HU1, and HU2 is where a contact of a wiring drawn out from the memory region MR is formed.

For example, the memory region MR and each of the hookup regions HU0, HU1, and HU2 extend along the Y-direction, and are arranged along the X-direction in the order of the hookup regions HU0, HU1, and HU2, and the memory region MR. However, it is not limited to the above, and the memory region MR and each of the hookup regions HU0, HU1, and HU2 may be designed in other shapes and arrangements.

For example, two hookup regions HU1 may be arranged to interpose the memory region MR and the hookup region HU2, or an annular hookup region HU1 may surround the memory region MR and the hookup region HU2. The hookup region HU1 does not necessarily have to be arranged between the hookup regions HU0 and HU2, as long as it is arranged in the periphery of a structure corresponding to at least the memory region MR and the hookup region HU2 of the memory cell array 10.

The memory cell array 10 includes conductors 30 to 33. The conductors 30 to 33 function respectively as the source line SL, the selection gate line SGS, the word line WL, and the selection gate line SGD. The number of each of the conductors 30 to 33 corresponds to the number of each of the source lines SL, selection gate lines SGS, word lines WL, and selection gate lines SGD.

As shown in FIG. 4, each of a plurality of conductors 30 that functions as the source lines SL extends along the X-direction. Furthermore, the plurality of conductors 30 are arranged along the Y-direction. A region in which each of the conductors 30 is provided is included in the memory region MR and the hookup region HU0.

In other words, each of the plurality of conductors 30 extended along the X-direction is arranged along the Y-direction in the memory region MR. Each of the end portions of the plurality of conductors 30 within the memory region MR is drawn out by the hookup region HU0.

In between the neighboring conductors 30 is provided a slit SLE in which an insulator is embedded to perform insulation between the neighboring conductors 30. The regions of the conductors 30 separated by the slit SLE each correspond to one block BLK.

For example, the slit SLE is provided for insulation in between each of the conductors 30 that functions as source lines SL0 and SL1. Each of the regions in which the source lines SL0 and SL1 are provided corresponds to the blocks BLK0 and BLK1.

As shown in FIG. 5, the conductor 31 that functions as the selection gate line SGS spreads out along the XY-plane. The region in which the conductor 31 is provided is included in the memory region MR and the hookup region HU1. The conductor 31 overlaps with the plurality of conductors 30 that correspond respectively to the blocks BLK0 and BLKn.

In other words, the conductor 31 that is spread out along the XY-plane is provided integrally on the entire memory region MR. The end portion of the conductor 31 within the memory region MR is drawn out by the hookup region HU1. The conductor 31, for example, is not included in the hookup region HU0, and each of the plurality of conductors 30 has a region that does not overlap with the conductor 31.

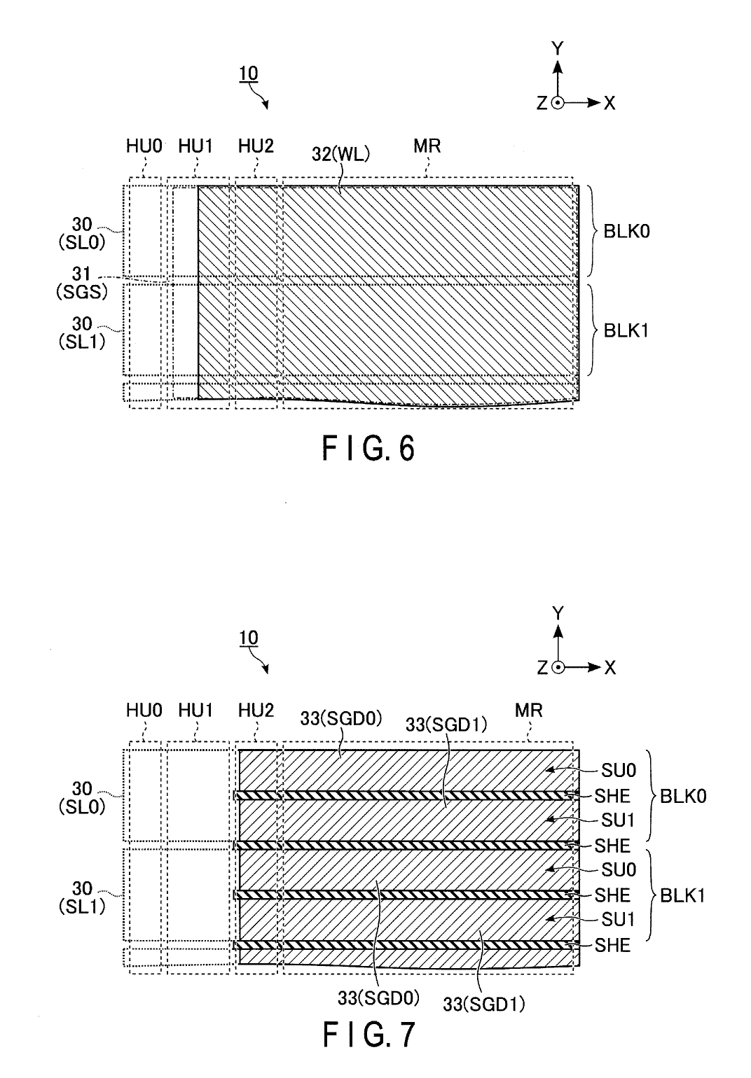

As shown in FIG. 6, the conductor 32 that functions as one word line WL spreads out along the XY-plane. The region in which the conductor 32 is provided is included in the memory region MR and the hookup region HU1, and is included in a region where the conductor 31 is provided.

In other words, in the memory region MR, the conductor 32 and the conductor 31 overlap. The end portion of the conductor 32 within the memory region MR is drawn out by the hookup region HU1 The conductor 32 within the hookup region HU1, for example, is provided smaller than the conductor 31. The conductor 31 has a region that does not overlap with the conductor 32. 6

As shown in FIG. 7, each of a plurality of conductors 33 that functions as the selected gate lines SGD extends along the X-direction. Furthermore, the plurality of conductors 33 are arranged along the Y-direction, and, for example, two conductors 33 overlap with respect to one conductor 30. A region in which each of the conductors 33 is provided is included in the memory region MR and the hookup region HU2.

In other words, each of the plurality of conductors 33 extended along the X-direction is arranged along the Y-direction in the memory region MR. In one conductor 30, the conductors 33 overlap in the same number as the number of string units SU included in one block BLK. Each of the end portions of the plurality of conductors 33 within the memory region MR is drawn out by the hookup region HU2.

Provided in between the neighboring conductors 33 is a slit SHE in which an insulator is embedded to perform insulation between the neighboring conductors 33. Each of the regions of the conductors 33 that are separated by the slit SHE corresponds to one string unit SU.

For example, in each of the blocks BLK0 and BLK1, in between the conductors 33 that function respectively as the selection gate lines SGD0 and SGD1, the slit SHE is provided for insulation. Each of the regions in which the selection gate lines SGD0 and SGD1 are provided corresponds to the string units SU0 and SU1.

Furthermore, in the same manner, also the slit SHE is provided for insulation in between the conductor 33 corresponding to the string unit SU1 of the block BLK0 and the conductor 33 corresponding to the string unit SU0 of the block BKL1.

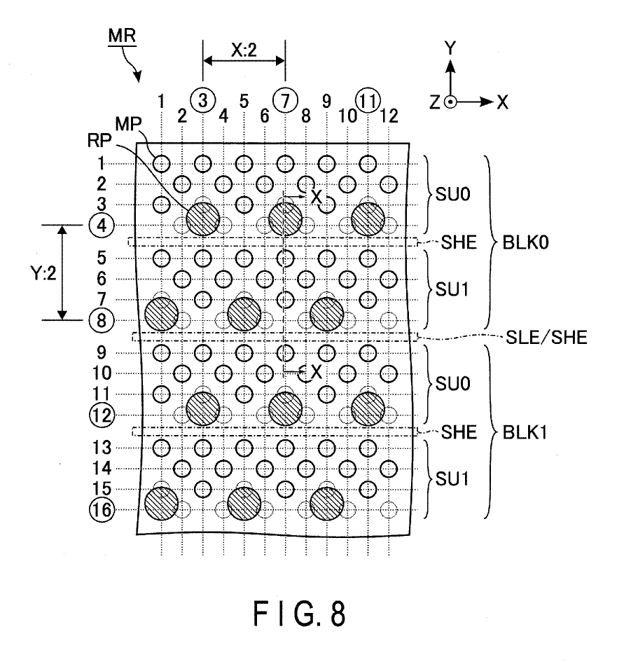

FIG. 8 shows an example of a plan layout of the memory cell array 10 in the memory region MR. In the following explanation, a coordinate system using numbers (X-coordinates) aligned along the X-direction and numbers (Y-coordinates) aligned along the Y-direction of a referenced plan layout diagram is used.

As shown in FIG. 8, the memory cell array 10 in the memory region MR includes a plurality of memory pillars MP and a plurality of replacement pillars RP.

Each of the plurality of memory pillars MP functions as, for example, one NAND string NS. The plurality of memory pillars MP are arranged, for example, in zigzags. Specifically, for example, the plurality of memory pillars MP are arranged respectively at a position where the X-coordinate is an odd number and the Y-coordinate is an odd number, and a position where the X-coordinate is an even number and the Y-coordinate is an even number. It is noted that the arrangement of the memory pillars MP at least overlaps a designated coordinate.

For example, the memory pillars MP whose Y-coordinates are “1” to “4” correspond to the string unit SU0 of the block BLK0. The memory pillars MP whose Y-coordinates are “5” to “8” correspond to the string unit SU1 of the block BLK0. The memory pillars MP whose Y-coordinates are “9” to “12” correspond to the string unit SU0 of the block BLK1. The memory pillars MP whose Y-coordinates are “13” to “16” correspond to the string unit SU1 of the block BLK1.

In this case, the slit SHE is arranged to each region between Y-coordinates “4” and “5”, Y-coordinates “8” and “9”, and Y-coordinates “12” and “13” that corresponds to a region between which each of the string units SU is adjacent. Furthermore, in a region between Y-coordinates “8” and “9” that corresponds to a region between the neighboring blocks BLK, a slit SLE is further arranged.

The arrangement is not limited to the above; therefore, the arrangement of each of the slits SLE and SHE can be changed as appropriate based on the arrangement of the memory pillar MP per string unit'SU and the number of string units SU included in one block BLK.

An interval between the neighboring Y-coordinates (for example, between Y-coordinates “4” and “5”) between which the slit SHE is arranged is designed wider than an interval of the neighboring Y-coordinates (for example, between Y-coordinates “2” and “3”) between which the slit SHE is not arranged.

In the present specification, a case in which each of the slits SLE and the slits SHE completely overlap has been exemplified in the XY-plane view; however, the embodiment is not limited thereto. For example, the widths of the slit SLE and the slit SHE may be different, and the slit SLE and the slit SHE may have a portion that does not overlap with each other.

Each replacement pillar RP includes a columnar insulator. The replacement pillar RP is provided inside a replace hole RH explained later on. In the manufacturing method of the semiconductor memory 1 explained later on, the replace hole RH is used when forming the conductors 30 and 32.

A plurality of replacement pillars RP are arranged, for example, in zigzags. At least one replacement pillar RP is arranged in each block BLK. Furthermore, each of the replacement pillars RP is arranged between two neighboring memory pillars MP among a plurality of memory pillars MP.

In the case where a region in which the memory pillars MP are arranged overlaps a region in which the replacement pillars RP are arranged, the arrangements of the memory pillars MP are omitted, and the arrangements of the replacement pillars RP are prioritized. The memory pillars MP that are omitted in the above manner are shown in dotted circles in FIG. 8.

The diameter of the replacement pillar RP is larger than the diameter of the memory pillar MP. The diameters of the pillars in the present specification are, for example, compared based on the diameters of the pillars of which portions have passed through a conductor provided on the same layer. Specifically, the diameter of, for example, the replacement pillar RP at a portion where the replacement pillar RP passes through the conductor 32 that functions as a word line WL7, is larger than the diameter of the memory pillar MP at a portion where the memory pillar MP passes through the conductor 32 that functions as the word line WL7.

Each interval at which the plurality of replacement pillars RP are arranged in the X direction and the Y direction is wider than the interval at which the plurality of memory pillars MP are arranged in the X direction and the Y direction.

For example, the plurality of replacement pillars RP are arranged respectively at a position where the X-coordinate is “4×i+3” (i is an integer equal to or greater than 0) and the Y-coordinate is “8×j+4” (j is an integer equal to or greater than 0), and at a position where the X-coordinate is “4×i+1” and the Y-coordinate is “8×j+8”. It is noted that arrangement of the replacement pillar RP at least overlaps a designated coordinate.

In this case, the number of memory pillars MP where the Y-coordinate is an even number (for example, Y-coordinate “2”) and is arranged along the X-direction between the X-coordinates (for example, X-coordinates “4” to “6”) of the replacement pillars RP neighboring in the X-direction becomes two (FIG. 8, X:2).

Furthermore, the number of memory pillars MP where the X-coordinate is an odd number (for example, X-coordinate “3”) and is arranged along the Y-direction between the Y-coordinates (for example, Y-coordinates “5” to “7”) of replacement pillars RP neighboring in a direction that intersects each of the X-direction and the Y-direction becomes two (FIG. 8, Y:2).

In other words, the number of memory pillars MP where the X-coordinate is an odd number (for example, X-coordinate “3”) and is arranged along the Y-direction between the Y-coordinates (for example, Y-coordinates “5” to “11”) of the replacement pillars RP neighboring in the Y-direction becomes four.

In the above manner, the memory cell array 10 included in the semiconductor memory 1 according to the first embodiment is provided with a plurality of replacement pillars RP that have passed through a plurality of conductors 32. Memory pillars MP are arranged on both sides of the replacement pillars RP in the Y-direction.

A column of a plurality of replacement pillars RP aligned in the X-direction (hereinafter, pillar column) includes a first column and a second column aligned in the Y-direction. For example, the first column corresponds to a plurality of replacement pillars RP whose Y-coordinate corresponds to “4”, and the second column corresponds to a plurality of replacement pillars RP whose Y-coordinate corresponds to “12”.

The conductor 31 is provided continuously in the Y-direction on both sides of the replacement pillars RP included in each pillar column, and is provided continuously in the Y-direction between the first column of the replacement pillars RP and the second column of the replacement pillars RP.

In the same manner, the conductor 32 is provided continuously in the Y-direction on both sides of the replacement pillars RP included in each pillar column, and is provided continuously in the Y-direction between the first column of the replacement pillars RP and the second column of the replacement pillars RP.

In other words, each of the conductors 31 and 32 through which the replacement pillars RP pass is formed continuously between a plurality of blocks BLK neighboring in the Y-direction in a layer on which the conductors 31 and 32 are formed.

This can be further rephrased as the conductor 31, with which the replacement pillars RP aligned in the X-direction come in contact on one side in the Y-direction, is provided continuously with the conductor 31 that comes in contact on the other side in the Y-direction, and the conductor 31, with which the replacement pillars RP aligned in the Y-direction come in contact on one side in the X-direction, is provided continuously with the conductor 31 that comes in contact on the other side in the X-direction.

In the same manner, the conductor 32, with which the replacement pillars RP aligned in the X-direction come in contact on one side in the Y-direction, is provided continuously with the conductor 32 that comes in contact on the other side in the Y-direction, and the conductor 32, with which the replacement pillars RP aligned in the Y-direction come in contact on one side in the X-direction, is provided continuously with the conductor 32 that comes in contact on the other side in the X-direction. In this manner, each of the conductors 31 and 32 is provided continuously between the replacement pillars RP neighboring in the X-direction and between the replacement pillars RP neighboring in the Y-direction, respectively.

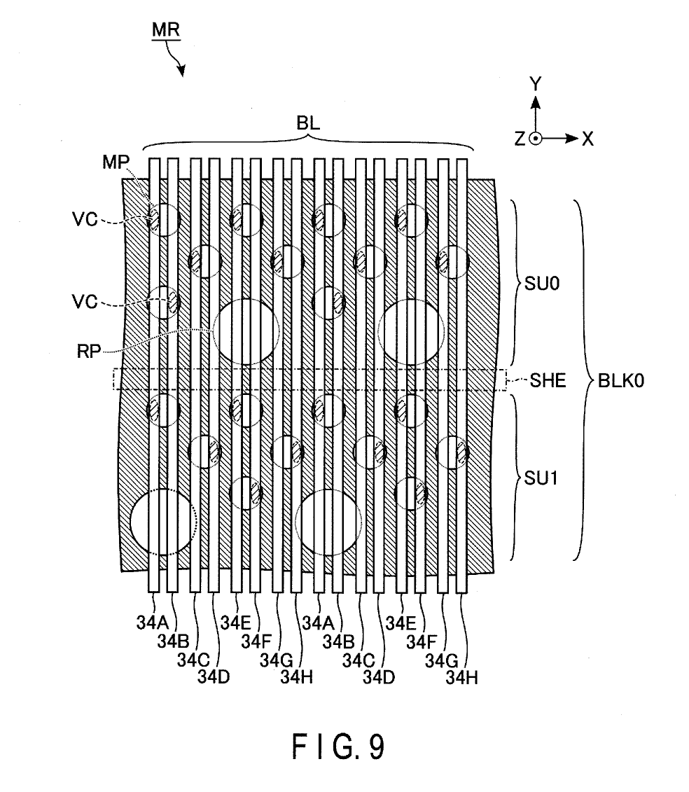

FIG. 9 shows a more specific example of a plan layout of the memory cell array 10 in the memory region MR, in which one block BLK0 is extracted from among a plurality of blocks BLK included in the memory cell array 10.

As shown in FIG. 9, in the memory cell array 10, a plurality of conductors 34 and a plurality of contacts VC are arranged corresponding to the arrangement of the memory pillars MP and the replacement pillars RP explained using FIG. 8.

Each of the plurality of conductors 34 extends in the Y-direction, and the plurality of conductors 34 are arranged in the X-direction. Each of the plurality of conductors 34 functions as a bit line BL. The number of conductors 34 corresponds to the number of bit lines BL. The plurality of contacts VC are provided respectively between each of the conductors 34 and a plurality of memory pillars MP corresponding to the conductors 34.

Specifically, two conductors 34 overlap with, for example, each of the memory pillars MP. Each of the memory pillars MP is electrically connected to one conductor 34 among a plurality of overlapping conductors through columnar contacts VC.

The connection relationship between the bit line BL and the memory pillar MP is such that, for example, a similar connection relationship is repeated for every eight bit lines BL. In FIG. 9, eight conductors 34 that correspond to a set of such eight bit lines BL are shown respectively as conductors 34A, 34B, 34C, 34D, 34E, 34F, 34G, and 34H.

For example, in the block BLK0, each of the conductors 34A and 34E is connected to one memory pillar MP within the string unit SU0 and one memory pillar MP within the string unit SU1.

Each of the conductors 34B, 34C, and 34G is connected to one memory pillar MP within the string unit SU0. Each of the conductors 34D, 34F, and 34H is connected to one memory pillar MP within the string unit SU1.

In this manner, in the semiconductor memory 1 according to the first embodiment, the number of memory pillars MP connected to each bit line BL may differ.

(Cross-Sectional Structure of Memory Cell Array 10)

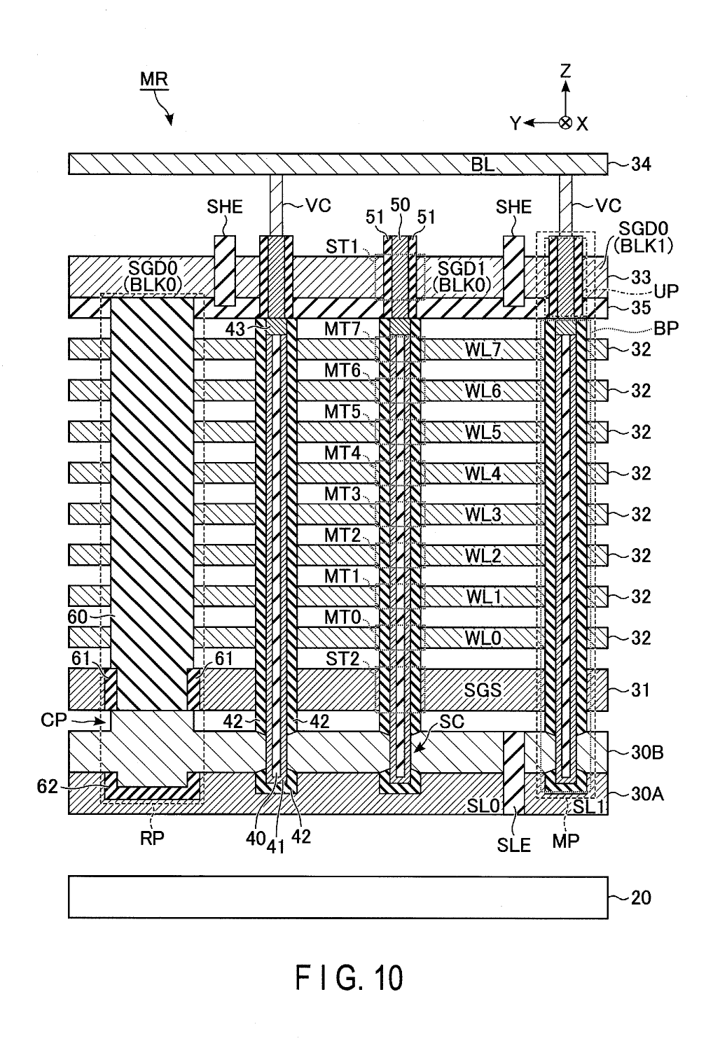

FIG. 10 is a cross-sectional view taken along line X-X in FIG. 8, and shows an example of a cross-sectional structure of the memory cell array 10 in the memory region MR. In the cross-sectional view referred to in the following explanation, constituent elements, such as interlayer insulation films, wirings, and contacts are omitted as appropriate so that the drawing is easily viewed.

Furthermore, in the following explanation, an “upper surface” indicates a surface that is parallel with a surface of the semiconductor substrate 20 and is distant from the semiconductor substrate 20 in a target constituent element. A “lower surface” indicates a surface that is parallel with the surface of the semiconductor substrate 20 and is closer to the semiconductor substrate 20 in the target constituent element.

As shown in FIG. 10, the memory cell array 10 in the memory region MR includes, for example, conductors 30A and 30B, the conductor 31, a plurality of conductors 32, a plurality of conductors 33, the conductor 34, a protective film 35, a plurality of memory pillars MP, and a plurality of contacts VC.

Conductors 30A and 30B are stacked above the semiconductor substrate 20 via the interlayer insulation film. In a region between the semiconductor substrate 20 and the conductor 30A, for example, circuits relating to the row decoder module 15 and the sense amplifier module 16, etc. are provided (not shown).

The conductors 30A and 30B include portions that are divided by the slit SLE from the upper surface of the conductor 30B to the lower surface of the conductor 30A. A combination of the conductors 30A and 30B in each divided region functions as one conductor 30 explained using FIG. 4.

Specifically, in the region shown in FIG. 10, with the slit SLE as a boundary, the conductors 30A and 30B that function as the source line SL0, and the conductors 30A and 30B that function as the source line SL1 are shown. As the conductor 30A, for example, a polysilicon obtained by doping phosphor is used, and as the conductor 30B, a polysilicon is used.

On the conductor 30B, the conductor 31 that functions as the selection gate line SGS is stacked via the interlayer insulation film. As the conductor 31, for example, a polysilicon obtained by doping phosphor is used.

On the conductor 31, a plurality of conductors 32 that function respectively as word lines WL0 to WL7 are stacked via an interlayer insulation film provided respectively therebetween. As the conductor 32, for example, tungsten is used.

On the conductor 32 of the uppermost layer, the protective film 35 is stacked via the interlayer insulation film. As the protective film 35, for example, an insulator such as a silicon oxide SiO₂ is used.

On the protective film 35, the conductor 33 that functions as the selection gate line SGD is stacked. The conductor 33 includes portions that are divided by the slits SHE from the upper surface of the conductor 33 to the lower surface of the conductor 33, or into the protective film 35. The conductor 33 in each divided region functions as one conductor 33 explained using FIG. 7.

Specifically, in the region shown in FIG. 10, with the slit SHE as a boundary, two conductors 33 that function as the selection gate lines SGD0 and SGD1 of the block BLK0, and the conductor 33 that functions as the selection gate line SGD0 of the block BLK1 are shown.

The memory pillars MP and the replacement pillars RP are provided in the structure formed by the conductors 30 to 33 explained above.

First, a detailed structure of the memory pillar MP will be explained.

The memory pillar MP includes a bottom pillar BP and an upper pillar UP.

The bottom pillar BP penetrates (passes through) each of the conductor 30B, the conductor 31, and the plurality of conductors 32. The lower surface of the bottom pillar BP, for example, enters inside the conductor 30A. The upper pillar UP penetrates (passes through) each of the protective film 35 and the conductor 33. A layer including the border between the bottom pillar BP and the upper pillar UP corresponds to a layer that includes a lower surface of the protective film 35.

The bottom pillar BP includes, for example, a core member 40, a semiconductor 41, a stacked film 42, and a conductor 43. The upper pillar UP includes, for example, a semiconductor 50 and a stacked film 51.

The core member 40, for example, is formed in a columnar shape that extends from a layer on which the conductor 30A is provided to a layer including the upper surface of the conductor 32 of the uppermost layer. In a XY-plane view, the core member 40 is provided at a center portion of the bottom pillar BP. As the core member 40, for example, an insulator such as a silicon oxide SiO₂ is used.

A side surface and a lower surface of the core member 40 are covered by the conductor 41. As the conductor 41, for example, an amorphous silicon is used. The conductor 41 has a side surface contact portion SC. The side surface contact portion SC is included in a layer on which the conductor 30B is provided.

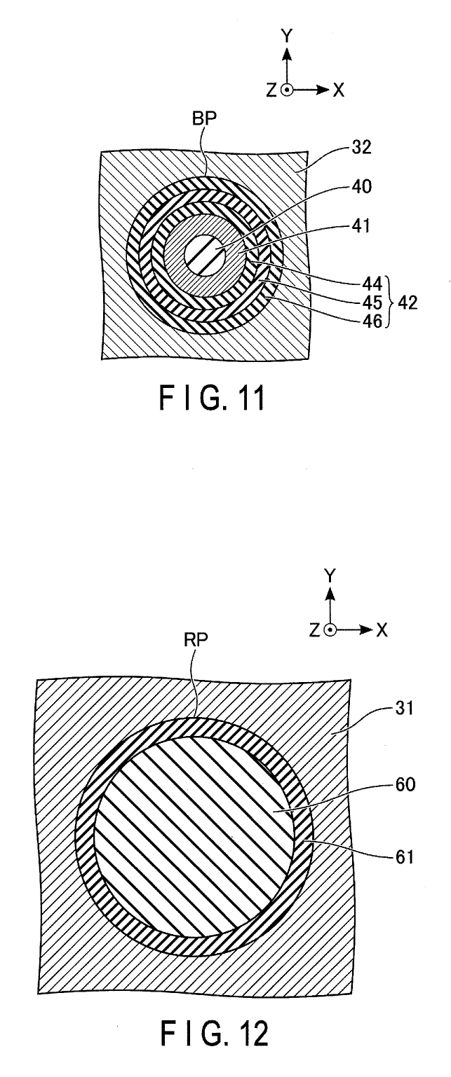

The conductor 41 is in contact with the conductor 30B at the side surface contact portion SC, and is electrically connected to the conductor 30B. The side surface and the lower surface excluding the side surface contact portion SC of the conductor 41 are covered with the stacked film 42. A detailed structure of the stacked film 42 is shown in FIG. 11. FIG. 11 shows an example of a detailed cross-sectional structure of the bottom pillar BP at a cross-sectional surface parallel to the surface of the semiconductor substrate 20.

As shown in FIG. 11, the stacked film 42 is configured by, for example, a tunnel oxide film 44, an insulation film 45, and a block insulation film 46. The tunnel oxide film 44 is formed on the side surface of the semiconductor 41 excluding the side surface contact portion SC. The insulation film 45 is formed on the side surface of the tunnel oxide film 44. The block insulation film 46 is formed on the side surface of the insulation film 45.

Returning to FIG. 10, the conductor 43 is formed on the upper surface of the core member 40 and the semiconductor 41, and is electrically connected to the semiconductor 41. As the conductor 43, for example, an amorphous silicon is used, and the conductor 43 may be formed integrally with the semiconductor 41. The side surface of the conductor 43 is covered with the stacked film 42.

The semiconductor 50, for example, is formed in a columnar shape that extends from a layer including the lower surface of the protective film 35 to a layer including the upper surface of the conductor 33. The semiconductor 50 is electrically connected to the conductor 43 at the bottom surface. As the semiconductor 50, for example, an amorphous silicon is used.

The side surface of the semiconductor 50 is covered with the stacked film 51. The stacked film 51, for example, includes the same stacked structure as the stacked film 42, and is configured to have a structure with different film thicknesses. The upper pillar UP may be formed of the same core member 40 as the bottom pillar BP.

In the manner mentioned above, the bottom pillar BP and the upper pillar UP are connected in the Z-direction.

In the configuration of such memory pillar MP, a portion at which the bottom pillar BP and the conductor 31 intersect functions as the selection transistor ST2. Each of the portions at which each of the bottom pillars BP and the plurality of conductors 32 intersect functions as memory cell transistors MT0 to MT7. A portion at which the upper pillar UP and the conductor 33 intersect functions as the selection transistor ST1.

That is, the insulation film 45 functions as a charge storage layer of the memory cell transistors MT. The semiconductor 41 functions as a channel of the memory cell transistors MT and the selection transistor ST2, and the semiconductor 50 functions as a channel of the selection transistor ST1.

A detailed structure of the replacement pillar RP will now be explained.

The replacement pillar RP penetrates each of the conductor 31, the plurality of conductors 32, and the protective film 35. For example, the upper surface of the replacement pillar RP is in contact with the conductor 33, and the lower surface of the replacement pillar RP enters into the conductor 30A.

In other words, the bottom surface of the replacement pillar RP is included in a layer on which the conductor 30A is provided. This can be further rephrased as the bottom surface of the replacement pillar RP stopping without penetrating the conductor 30A that functions as the source line SL.

The replacement pillar RP includes, for example, an insulator 60, insulation films 61 and 62, and a part of the conductor 30B.

The insulator 60, for example, is formed in a columnar shape that extends from a layer on which the conductor 31 is provided to the upper surface of the protective film 35. The insulation film 61 is formed cylindrically at a layer on which the conductor 31 is formed. A detailed structure of the insulation film 61 is shown in FIG. 12. FIG. 12 shows an example of a detailed cross-sectional structure of the replacement pillar RP at a cross-sectional surface parallel to the surface of the semiconductor substrate 20.

As shown in FIG. 12, the insulation film 61 is formed between, for example, the insulator 60 and the conductor 31. In other words, in a layer on which the conductor 31 is formed, for example, an inner wall of the insulation film 61 is in contact with the insulator 60, and an outer wall of the insulation film 61 is in contact with the conductor 31.

Returning to FIG. 10, on the lower surface of the insulator 60, a part of the conductor 30B is in contact. At a contact portion CP of the conductor 30B and the insulator 60, the conductor 30B is, for example, formed in a columnar shape.

That is, a part of the conductor 30B included in the region of the replacement pillar RP may include a columnar portion that protrudes from the upper surface of the conductor 30B. In some cases, the contact portion CP may enter inside a layer on which the conductor 31 is formed. Even in such case, the conductor 30B and the conductor 31 are insulated by the insulation film 61.

The insulation film 62 is formed between the conductor 30A and the conductor 30B in a layer on which the region of the replacement pillar RP and the conductor 30A are formed. That is, the insulation film 62 is formed on the bottom portion of the replacement pillar RP. A columnar portion (convex portion) protruding from the lower surface of the conductor 30B may also enter the layer on which the region of the replacement pillar RP and the conductor 30A are formed.

A structure of an upper layer above the conductor 33 will now be explained. The conductor 34 is provided on the upper layer above the upper surface of the memory pillar MP via the interlayer insulation film.

The conductor 34 is electrically connected to one corresponding memory pillar MP every string unit SU. Specifically, the contact VC is formed on the semiconductor 50 inside one memory pillar MP among the plurality of memory pillars MP electrically connected to the conductor 30 that corresponds, for example, to the source line SL0, and the conductor 34 is formed on such contact VC. Similarly, the contact VC is formed on the semiconductor 50 inside one memory pillar MP among the plurality of memory pillars MP electrically connected to the conductor 30 that corresponds to the source line SL1, and the conductor 34 is formed on such contact VC.

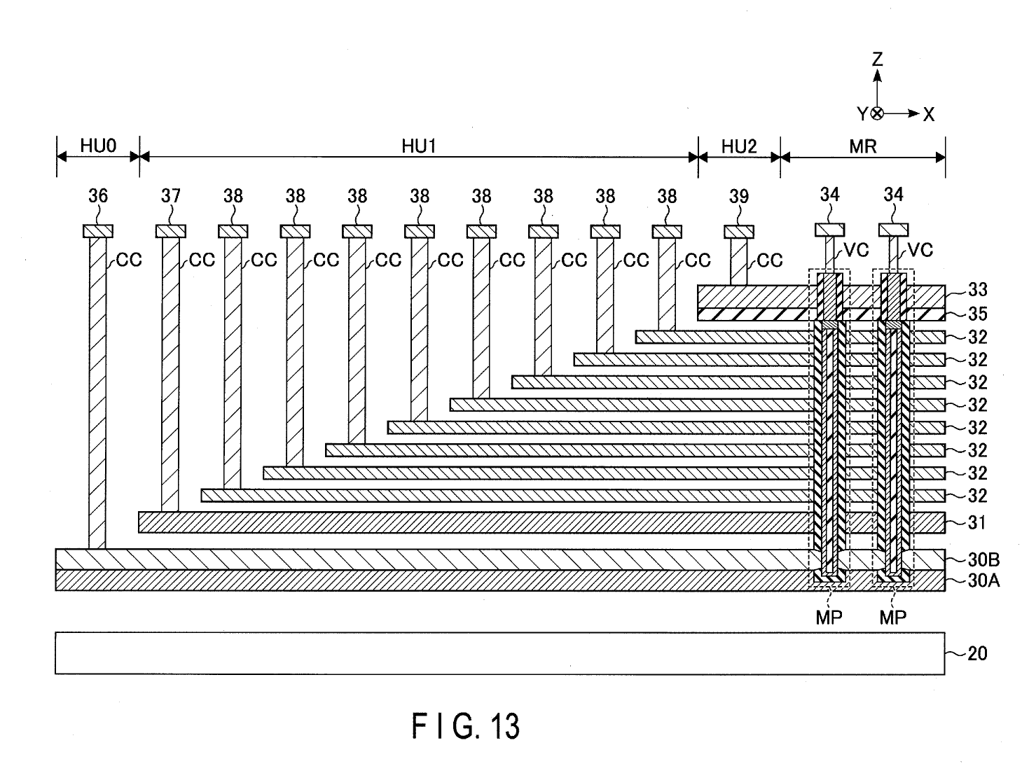

FIG. 13 shows an example of a cross-sectional structure of the memory cell array 10 in the hookup region HU. In FIG. 13, the structure of the memory pillars MP in the above-mentioned memory region MR are also shown so that the layer structure of the memory cell array 10 can be easily understood.

As shown in FIG. 13, the memory cell array 10 in the hookup regions HU0, HU1, and HU2 includes, for example, an end portion of each of the conductors 30 to 33, an end portion of the protective film 35, a conductor 36, a conductor 37, a plurality of conductors 38, a conductor 39, and a plurality of contacts CC.

In the hookup regions HU0, HU1, and HU2, the end portion of each of the conductors 30 to 33 is, for example, provided step-like. However, in the hookup regions HU0, HU1, and HU2, each of the end portions of the conductors 30 to 32 is not limited to this as long as it at least has a portion that does not overlap with the conductors 31 to 33 provided on the upper layer.

In the hookup region HU0, a columnar contact CC is formed on an end portion of the conductor 30B, and the conductor 36 is formed on the contact CC.

In the hookup region HU1, a columnar contact CC is formed on an end portion of the conductor 31, and the conductor 37 is formed on the contact CC. On the end portion of each of the conductors 32, each columnar contact CC is formed, and on the contact CC formed on the conductor 32, each of the conductors 38 is formed.

In the hookup region HU2, a columnar contact CC is formed on an end portion of the conductor 33, and the conductor 39 is formed on the contact CC.

Each of the conductors 36 to 39 explained above is electrically connected to the row decoder module 15 in a region that is not shown. The layer on which each of the conductors 36 to 39 is formed may be the same or different. Furthermore, the layer on which each of the conductors 36 to 39 is formed may be the same as or different from the layer on which the conductor 34 is formed.

In the structure of the memory cell array 10 explained above, a plurality of conductors 31 provided on a plurality of layers may be allocated to the selection gate line SGS, and different materials may be used for the conductor 31 provided on the plurality of layers. The number of conductors 32 is designed based on the number of word lines WL.

The bottom pillar BP may have a structure in which a plurality of pillars are connected in the Z-direction. The memory pillar MP and the conductor 34 may be electrically connected via two or more contacts VC, or may be electrically connected via other wirings. Each of the end portions of the conductors 30 to 33 and the corresponding conductors 36 to 39 may be electrically connected via two or more contacts CC or may be electrically connected via other wirings.

In the present specification, a structure in which the replacement pillar RP passes through (penetrates) the conductors 31 and 32 is exemplified; however, the replacement pillar RP may also pass through (penetrate) the conductor 33. In this case, in the manufacturing process of the semiconductor memory, the replace hole RH is used when forming the conductors 30, 32, and 33. In other words, in this case, the conductor 33 is formed by the same manufacturing process as the conductor 32.

[1-1-3] Configuration of Driver Module 14

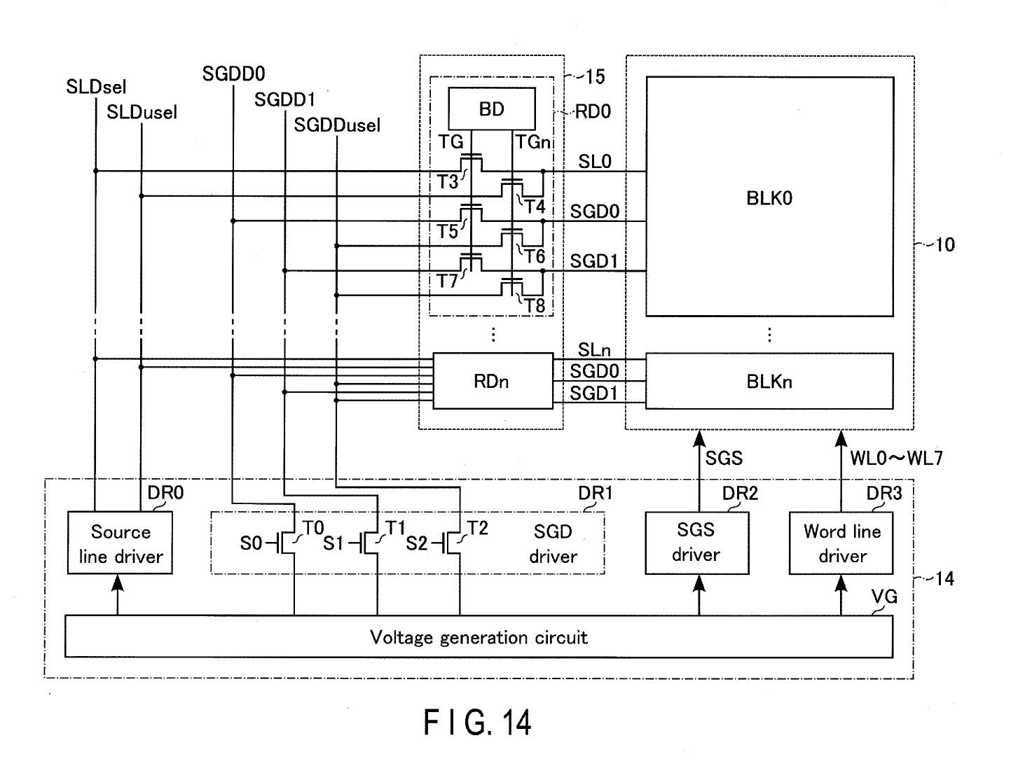

FIG. 14 shows an example of a circuit configuration of the driver module 14. In FIG. 14, configuration examples of the memory cell array 10 and the row decoder module 15 that relate to the driver module 14 are also shown.

As shown in FIG. 14, the driver module 14 includes a voltage generation circuit VG, a source line driver DR0, an SGD driver DR1, an SGS driver DR2, and a word line driver DR3.

Based on the control of the sequencer 13, the voltage generation circuit VG generates a voltage to be applied to, for example, each selected and non-selected source lines SL, selection gate lines SGD0 and SGD1 corresponding to a selected block BLK, selection gate line SGD corresponding to a non-selected block BLK, selection gate line SGS, and selected and non-selected word line WL.

The voltage generation circuit VG transfers each corresponding voltage among the generated plurality of kinds of voltages to the source line driver DRO, the SGD driver DR1, the SGS driver DR2, and the word line driver DR3.

Based on the control of the sequencer 13 and the voltage transferred from the voltage generation circuit VG, the source line driver DRO applies a voltage corresponding to the selected source line SL to a signal line SLDsel, and applies a voltage corresponding to the non-selected source line SL to a signal line SLDusel.

Based on the control of the sequencer 13 and the voltage transferred from the voltage generation circuit VG, the SGD driver DR1 applies a voltage corresponding to the selection gate lines SGD0 and SGD1 of the selected block BLK to each signal line SGDD0 and SGDD1, and applies a voltage corresponding to the selection gate line SGD of the non-selected block BLK to a signal line SGDDusel.

Specifically, the SGD driver DR1 includes, for example, transistors T0 to T3.

The voltage corresponding to the selection gate line SGD0 of the selected block BLK is applied to one end of the transistor T0, and the other end of the transistor T0 is connected to the signal line SGDD0. A control signal S0 is input to a gate of the transistor T0.

The voltage corresponding to the selection gate line SGD1 of the selected block BLK is applied to one end of the transister T1, and the other end of the transistor T1 is connected to the signal line SGDD1. A control signal S1 is input to a gate of the transister T1.

The voltage corresponding to the selection gate line SGD of the non-selected block BLK is applied to one end of the transistor T2, and the other end of the transistor T2 is connected to the signal line SGDDusel. A control signal S2 is input to a gate of the transistor T2.

Each of the control signals S0 to S2 explained above is generated by, for example, the sequencer 13. For example, in the case where the control signal S2 is a level “H” voltage, the transistor T2 comes to be in an ON-state, and the voltage generated by the voltage generation circuit VG is applied to the signal line SGDDusel. On the other hand, in the case where the control signal. S2 is a level “L” voltage, the transistor T2 comes to be in an OFF-state, and the signal line SGDDusel becomes a floating state.

The SGS driver DR2 applies a desired voltage to the selection gate line SGS based on the control of the sequencer 13 and the voltage transferred from the voltage generation circuit VG.

Based on the control of the sequencer 13, the voltage transferred from the voltage generation circuit VG, and a page address PA, the wire line driver DR3 applies a desired voltage to each of the selected word line WL and the non-selected word line among the word lines WL0 to WL7.

The circuit configuration of the driver module 14 is not limited to the configuration explained above. For example, the number of transistors included in the SGD driver DR1 may be changed as appropriate in accordance with the number of string units SU.

[1-1-4] Configuration of Row Decoder Module 15

An example of a circuit configuration of the row decoder module 15 will be explained still with reference to FIG. 14. The row decoder 15 includes row decoders RD0 to RDn. FIG. 14 shows a detailed circuit configuration of row decoder RD0 among the row decoders RD0 to RDn.

Each of the row decoders RD0 to RDn is associated with blocks BLK0 to BLKn. That is, one row decoder RD is associated with each block BLK. Each of the row decoders RD includes transistors T3 to T8 and a block decoder BD.

Each of the transistors T3 to T8 is an n-channel MOS transistor.

One end of the transistor T3 is connected to a signal line SLDsel, and the other end of the transistor T3 is connected to a source line SL0. One end of the transistor T4 is connected to a signal line SLDusel, and the other end of the transistor T4 is connected to the source line SL0.

One end of the transistor T5 is connected to a signal line SGDD0, and the other end of the transistor T5 is connected to a selection gate line SGD0. One end of the transistor T6 is connected to a signal line SGDDusel, and the other end of the transistor T6 is connected to the selection gate line SGD0.

One end of the transistor T7 is connected to a signal line SGDD1, and the other end of the transistor T7 is connected to a selection gate line SGD1. One end of the transistor T8 is connected to a signal line SGDDusel, and the other end of the transistor T8 is connected to the selection gate line SGD1.

The block decoder BD decodes the block address BA. Based on the decoding result, the block decoder BD applies a predetermined voltage to each transfer gate line TG and TGn.

The transfer gate line TG is commonly connected to a gate of each of the transistors T3, T5, and T7. The transfer gate line TGn is commonly connected to a gate of each of the transistors T4, T6, and T8. A signal to be transferred by the block decoder BD to the transfer gate line TGn is a signal obtained by inverting a signal to be transferred to the transfer gate line TG.

Specifically, when performing various operations, the block decoder BD corresponding to a selected BLK applies a level “H” voltage to the transfer gate line TG, and applies a level “L” voltage to the transfer gate line TGn.

As a result, in the selected block BLK, the transistors T3, T5, and T7 come to be in an ON-state, and the transistors T4, T6, and T8 come to be in an OFF-state. In other words, the voltage applied to each of the signal lines SLDsel, SGDD0, and SGDD1 is applied to each of the source line SL and the selection gate lines SGD0 and SGD1 of the selected block BLK.

On the other hand, the block decoder BD corresponding to the non-selected block BLK applies a level “L” voltage to the transfer gate line TG, and applies a level “H” voltage to the transfer gate line TGn.

As a result, in the non-selected block BLK, the transistors T3, T5, and T7 come to be in an OFF-state, and the transistors T4, T6, and T8 come to be in an ON-state. In other words, the voltage applied to the signal line SLDusel is applied to the source line SL of the non-selected block BLK, and the voltage applied to the signal line SGDDusel is applied to each of the selection gate lines SGD0 and SGD1 of the non-selected block BLK.

In the above manner, the row decoder module 15 is capable of selecting a block BLK to execute an operation.

The circuit configuration of the row decoder module 15 is not limited to the configuration explained above. For example, the number of transistors included in the row decoder RD may be changed as appropriate in accordance with the number of string units SU. Furthermore, the voltage that the voltage generation circuit VG applies to each of the selection gate line SGS and the word lines WL0 to WL7 may be applied via the circuits inside the row decoder module 15.

[1-1-5] Configuration of Sense Amplifier Module 16

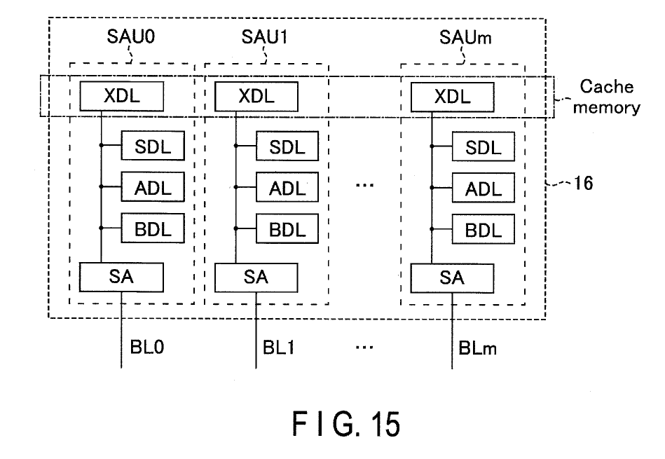

FIG. 15 shows an example of a circuit configuration of the sense amplifier module 16.

As shown in FIG. 15, the sense amplifier module 16 includes, for example, sense amplifier units SAU0 to SAUm.

Each of the sense amplifier units SAU0 to SAUm is associated with each of the bit lines BL0 to BLm. Each sense amplifier unit SAU includes, for example, a sense amplifier SA, and latch circuits SDL, ADL, BDL, and XDL.

The sense amplifier SA and the latch circuits SDL, ADL, BDL, and XDL are connected to each other so that data can be transmitted and received therebetween. In a read operation, for example, the sense amplifier SA senses data that is read to a corresponding bit line BL, and determines whether the read data is “0” or “1”. Each of the latch circuits SDL, ADL, BDL, and XDL temporarily holds the read data and the write data, etc.

The latch circuit XDL is connected to an input/output circuit that is not shown, and is used to input and output data between the sense amplifier unit SAU and the input/output circuit of the semiconductor memory 1. In other words, the latch circuit XDL functions as, for example, a cache memory of the semiconductor memory 1. For example, even if the latch circuits SDL, ADL, and BDL were in use, the semiconductor memory 1 can be in a ready state if the latch circuit XDL is unused.

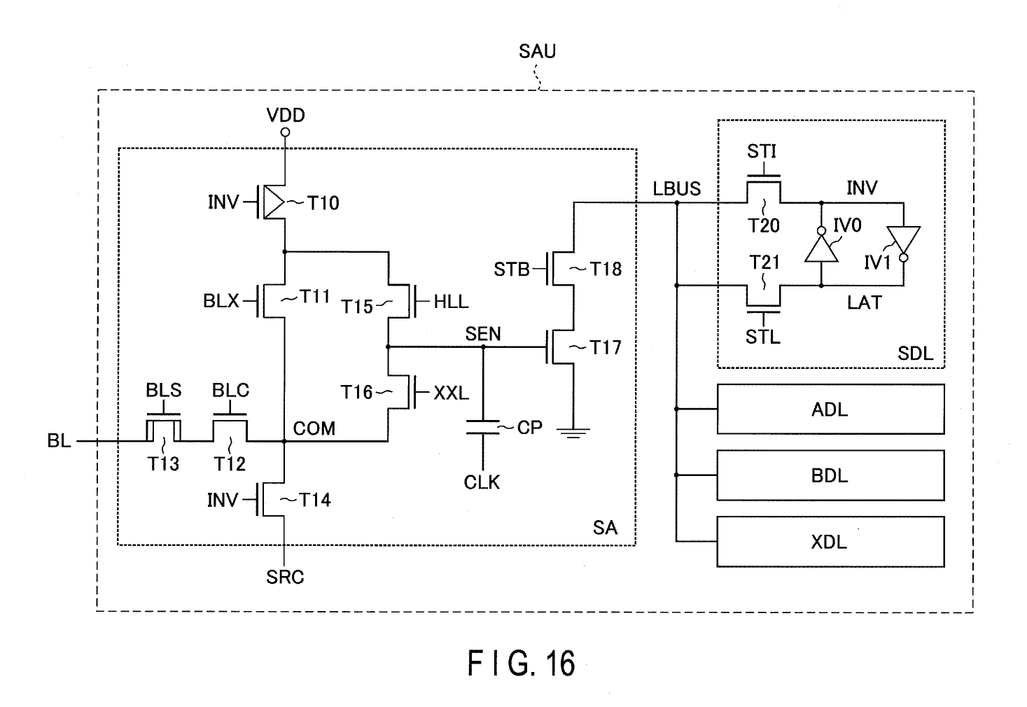

FIG. 16 shows an example of a detailed circuit configuration of a sense amplifier unit SAU.

As shown in FIG. 16, the sense amplifier SA includes, for example, transistors T10 to T18, and a capacitor CP. The latch circuit SDL includes, for example, inverters IV0 and IV1, and transistors T20 and T21.

The transistor T10 is a p-channel MOS transistor, and each of the transistors T11 to T18, T20, and T21 is an re-channel MOS transistor. Since the circuit configurations of the latch circuits ADL, BDL, and XDL are similar to, for example, the circuit configuration of the latch circuit SDL, the explanations thereof will be omitted.

One end of the transistor T10 is connected to a power supply line, and a gate of the transistor T10 is connected to a node INV. A voltage VDD, which is a power supply voltage of, for example, the semiconductor memory 1, is applied to the power supply line to which one end of the transistor T10 is connected.

One end of the transister T11 is connected to the other end of the transistor T10, the other end of the transister T11 is connected to a node COM, and a control signal BLX is input to a gate of the transistor T11.

One end of the transistor T12 is connected to the node COM, and a control signal BLC is input to a gate of the transistor T12. The transistor T13 is, for example, a high-breakdown voltage n-channel MOS transistor, whose one end is connected to the other end of the transistor T12, and the other end is connected to a corresponding bit line BL. A control signal BLS is input to a gate of the transistor T13.

One end of the transistor T14 is connected to the node COM, the other end of the transistor T14 is connected to a node SRC, and a gate of the transistor T14 is connected to a node INV. A voltage VSS is applied to the node SRC, which is, for example, a ground voltage of the semiconductor memory 1.

One end of the transistor T15 is connected to the other end of the transistor T10, the other end of the transistor T15 is connected to a node SEN, and a control signal HLL is input to a gate of the transistor T15.

One end of the transistor T16 is connected to the node SEN, the other end of the transistor T16 is connected to the node COM, and a control signal XXL is input to a gate of the transistor T16.

One end of the transistor T17 is grounded, and a gate of the transistor T17 is connected to the node SEN.

One end of the transistor T18 is connected to the other end of the transistor T17, the other end of the transistor T18 is connected to a bus LBUS, and a control signal STB is input to a gate of the transistor T18. One end of the capacitor CP is connected to the node SEN, and a clock CLK is input to the other end of the capacitor CP.

An input node of an inverter IV0 is connected to a node LAT, and an output node of the inverter IV0 is connected to a node INV. An input node of an inverter IV1 is connected to the node INV, and an output node of the inverter IV1 is connected to the node LAT.

One end of the transistor T20 is connected to the node INV, the other end of the transistor T20 is connected to the bus LBUS, and a control signal STI is input to a gate of the transistor T20.

One end of the transistor T21 is connected to the node LAT, the other end of the transistor T21 is connected to the bus LBUS, and a control signal STL is input to a gate of the transistor T21.

Each of the control signals BLX, BLC, BLS, HLL, XXL, and STB explained above is generated by, for example, the sequencer 13. A timing at which the sense amplifier SA determines the data read to the bit line BL is based on a timing at which the control signal STB is asserted.

In the following explanation, “the control signal STB is asserted” corresponds to temporarily changing the control signal STB from level “L” to level “H by the sequencer 13. Depending on the configuration of the sense amplifier module 16, in some cases, the operation such as “the control signal STB is asserted” corresponds to temporarily changing the control signal STB from level “H” to level “L by the sequencer 13.

The circuit configuration of the sense amplifier module 16 is not limited to the configuration explained above. For example, the number of latch circuits included in the sense amplifier unit SAU may be changed as appropriate in accordance with the number of bits of data stored in the memory cell transistor MT.

[1-2] Manufacturing Method of Semiconductor Memory 1

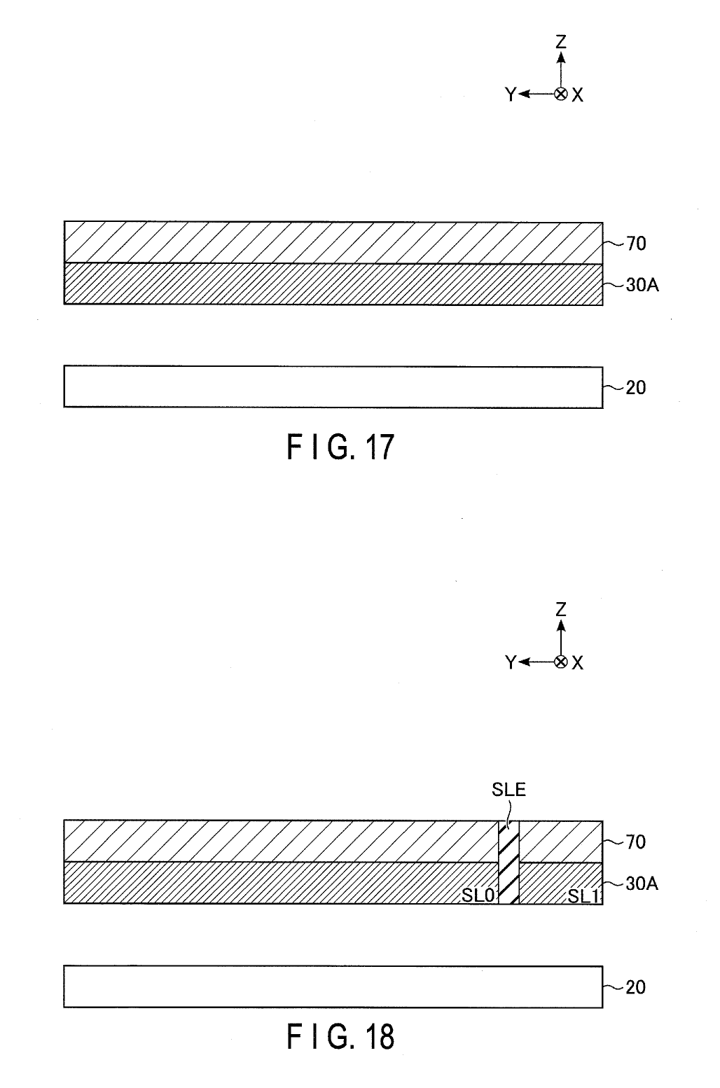

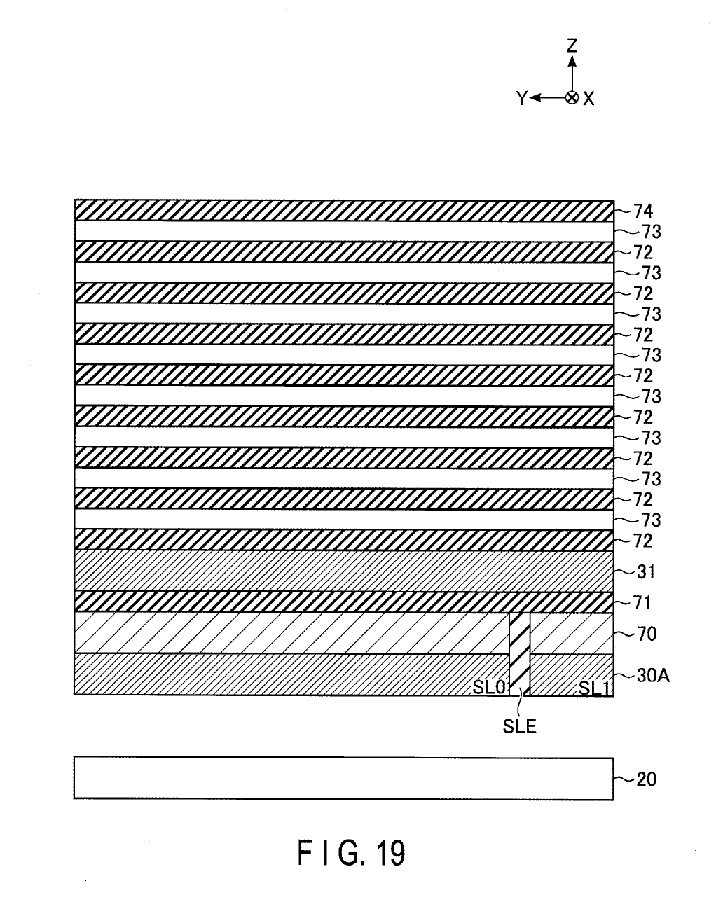

FIG. 17 to FIG. 30 will be used to explain a manufacturing process from a process of dividing the source line SL by the slit SLE to forming the replacement pillar RP.

Each of FIG. 17 to FIG. 30 shows an example of a manufacturing process of the semiconductor memory 1 according to the first embodiment, and shows a cross-sectional structure or a plan layout of a structure formed on the memory region MR. The manufacturing process exemplified below starts from a structure in the middle of a manufacturing process shown in FIG. 17.

As shown in FIG. 17, the conductor 30A is formed on the semiconductor substrate 20 via the interlayer insulation film, and a sacrifice member 70 is formed on the conductor 30A. The conductor 30A is made of, for example, phosphor-doped polysilicon, and the sacrifice member 70 is made of, for example, polysilicon.

Furthermore, in a region between the semiconductor substrate 20 and the conductor 30A, circuits related to, for example, the row decoder module 15 and the sense amplifier module 16 are provided; however, in each of FIG. 17 to FIG. 30, the drawings of these circuits are omitted.

As shown in FIG. 18, the slit SLE is formed.

Specifically, for example, first, a mask having an opening at a region where the slit SLE is to be formed is formed on the sacrifice member 70 by photolithography, etc. The slit formed by etching using the mask is formed to at least reach the lower surface of the conductor 30A from the upper surface of the sacrifice member 70, and divides the sacrifice member 70 and the conductor 30A for each block BLK.

An insulator (for example, silicon oxide SiO₂) is embedded into the slit formed by this etching, that is, a portion at which the sacrifice member 70 and the conductor 30A are divided. This insulator is also formed on, for example, the sacrifice member 70; however, is removed by, for example, Chemical Mechanical Polishing (CMP). Each of the conductors 30A divided in the present process functions as the source line SL.

Then, as shown in FIG. 19, an insulation film 71 is formed on the sacrifice member 70 and the slit SLE. The conductor 31 is formed on the insulation film 71. An insulation film 72 and a replacement member 73 are alternately stacked on the conductor 31. An insulation film 74 is formed on the uppermost replacement member 73.

The insulation films 71, 72, and 74 are oxide films made of, for example, silicon oxide SiO₂. In the manufacturing process, the insulation film 71 may be obtained by flattening the insulator formed on the sacrifice member 70 and into the slit as explained using FIG. 18.

The conductor 31 is made of, for example, phosphor-doped polysilicon, and is made using the same material as the conductor 30A. This conductor 31 functions as the selection gate line SGS.

The replacement member 73 is, for example, a nitride film made of, for example, silicon nitride SiN. The number of layers in which the replacement member 73 is formed corresponds to, for example, the number of word lines WL through which the bottom pillar BP passes. For example, each of the plurality of replacement members 73 corresponds to word lines WL0 to WL7 in this order from the bottom layer.

Then, a plurality of memory holes MH and a plurality of replace holes RH are formed.

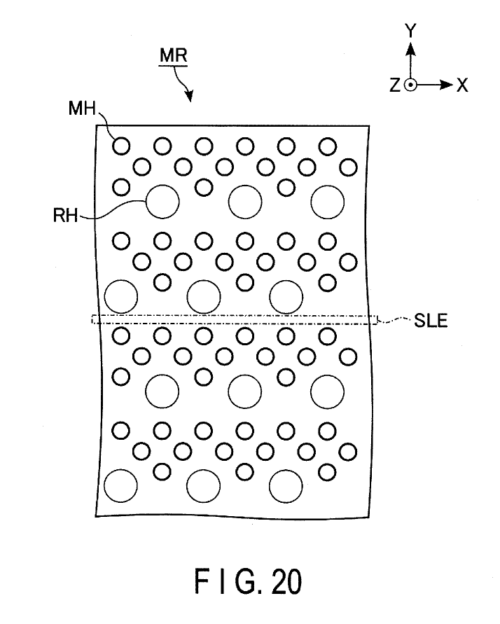

Specifically, for example, as shown in FIG. 20, first, a mask having an opening at regions where the plurality of memory holes MH and the plurality of replace holes RH are to be formed is formed on the insulation film 74 by photolithography, etc.

Each of the regions at which the memory hole MH and the replace hole RH are to be formed corresponds to the regions at which the memory pillar MP and the replacement pillar RP are to be formed that is explained using FIG. 8. In the XY-plane view, the regions at which each of the memory pillars MP and the replacement pillars RP is formed are preferred not to overlap with the region at which the slit SLE is provided.

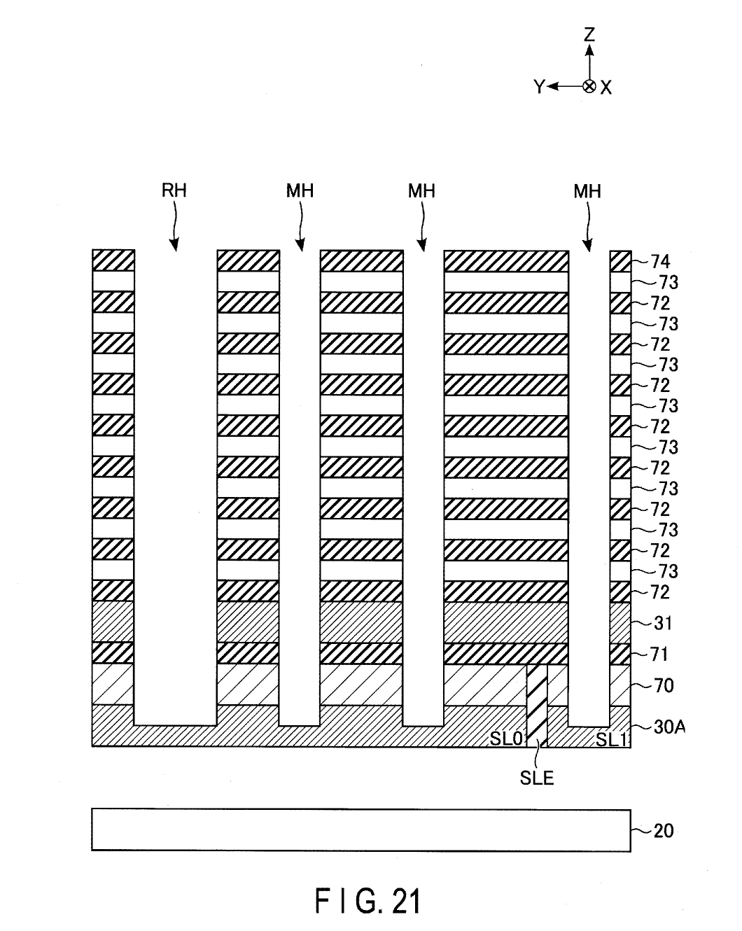

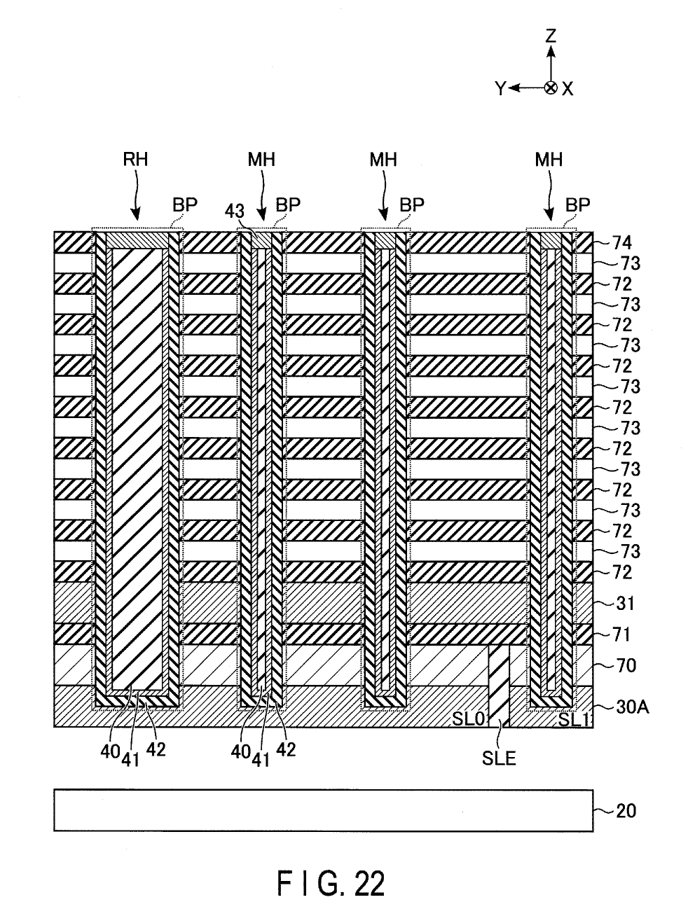

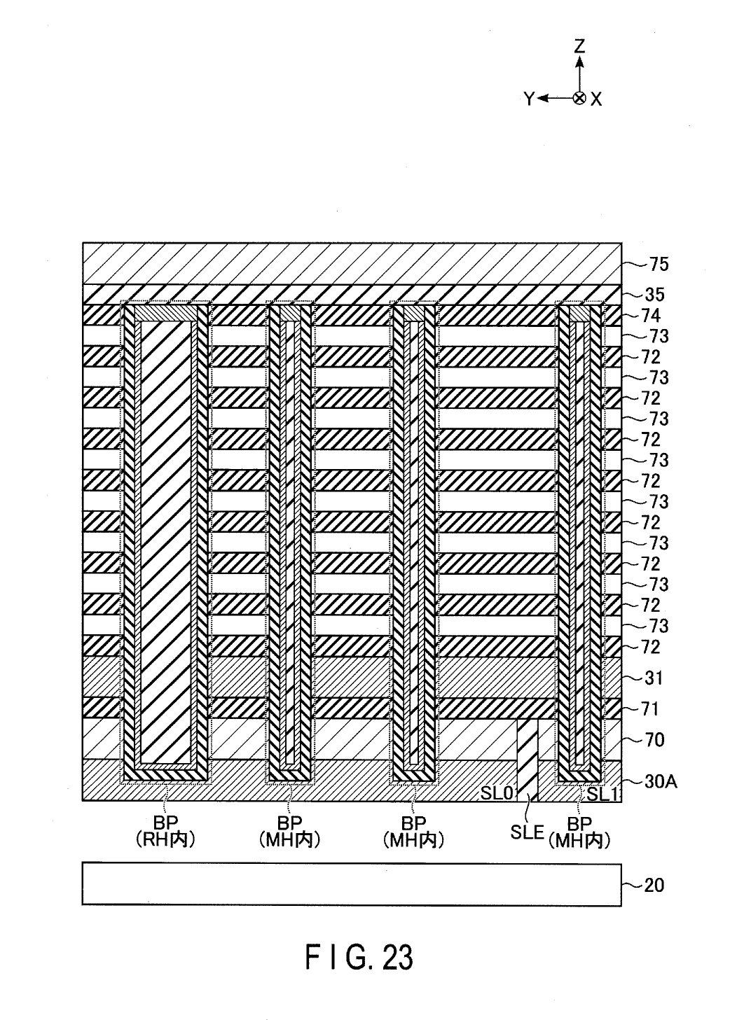

As shown in FIG. 21, by an etching using the mask explained in FIG. 20, each of the plurality of memory holes MH and the plurality of replace holes RH are formed, for example, from the upper surface of the insulation film 74 so as to reach a layer on which the conductor 30A is provided. The bottom part of each of the memory hole MH and the replace hole RH may intrude into the conductor 30A.

In the present process, an anisotropic etching, such as a Reactive Ion Etching (RIE), is used. In the etching in the present process, the conductor 31 may be used as an etching stopper.

In this case, first, the memory hole MH and the replace hole RH are formed to reach the conductor 31 under an etching condition in which the selection ratio of the conductor 31 is low. The memory hole MH and the replace hole RH penetrate the conductor 31 by an etching condition that allows the conductor 31 to be processed, and have each bottom part reach the conductor 30A.

In this manner, by using the conductor 31 as an etching stopper, the position of the lower end of each of the memory hole MH and the replace hole RH can be aligned. As a result, each of the memory hole MH and the replace hole RH can be suppressed from intruding deeply into the conductor 30A.

In the manner shown in FIG. 22, the bottom pillars BP are formed inside each of the plurality of memory holes MH and the plurality of replace holes RH.

Specifically, for example, the stacked film 42 (the block insulation film 46, the insulation film 45, and the tunnel oxide film 44), the semiconductor 41, and the core member 40 are formed respectively in this order on the upper surface of the insulation film 74, the inner walls of the plurality of memory holes MH, and the inner walls of the plurality of replace holes RH.

The stacked film 42, the semiconductor 41, and the core member 40 that are formed on the upper layer above the upper surface of the insulation film 74 are removed, and the core member 40 provided on each of the upper parts of the plurality of memory holes MH and the upper parts of the plurality of replace holes RH is removed. The upper parts of each of the memory holes MH and the replace holes RH are included in the upper layer above the upper surface of the replacement member 73 provided on the uppermost layer.

Then the conductor 43 is formed at a region from which the core member 40 has been removed inside each of the memory holes MH and the replace holes RH.

In this manner, in the present process, a structure similar to that of the bottom pillar BP is formed not only inside the memory hole MH, but also inside the replace hole RH.

Now, as shown in FIG. 23, the protective film 35 is formed on the upper surface of the insulation film 74 and on the upper surface of the bottom pillars BP formed inside each of the memory holes MH and the replace holes RH. A sacrifice member 75 (for example, amorphous silicon) is formed on the protective film 35.

Then, the structure of the bottom pillar BP formed inside the replace hole RH is removed.

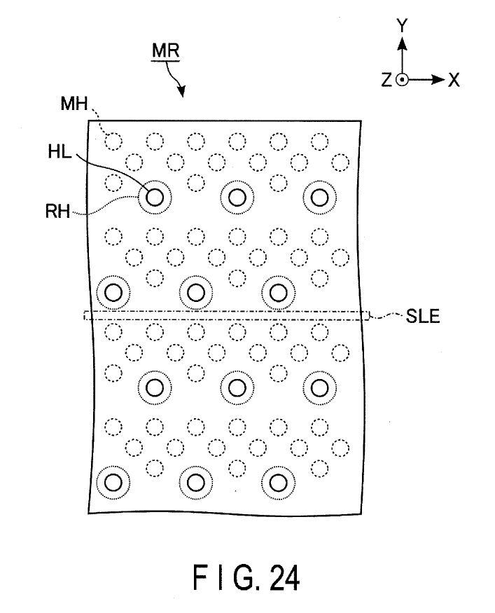

Specifically, for example, as shown in FIG. 24, first, a mask having an opening that is to overlap each of the plurality of replace holes RH is formed on the sacrifice member 75 by photolithography, etc.

By the etching using this mask, a plurality of holes HL are formed from the upper surface of the sacrifice member 75 to reach the lower surface of the protective film 35. In this manner, the upper surface of the bottom pillar BP formed inside the replace hole RH is exposed.

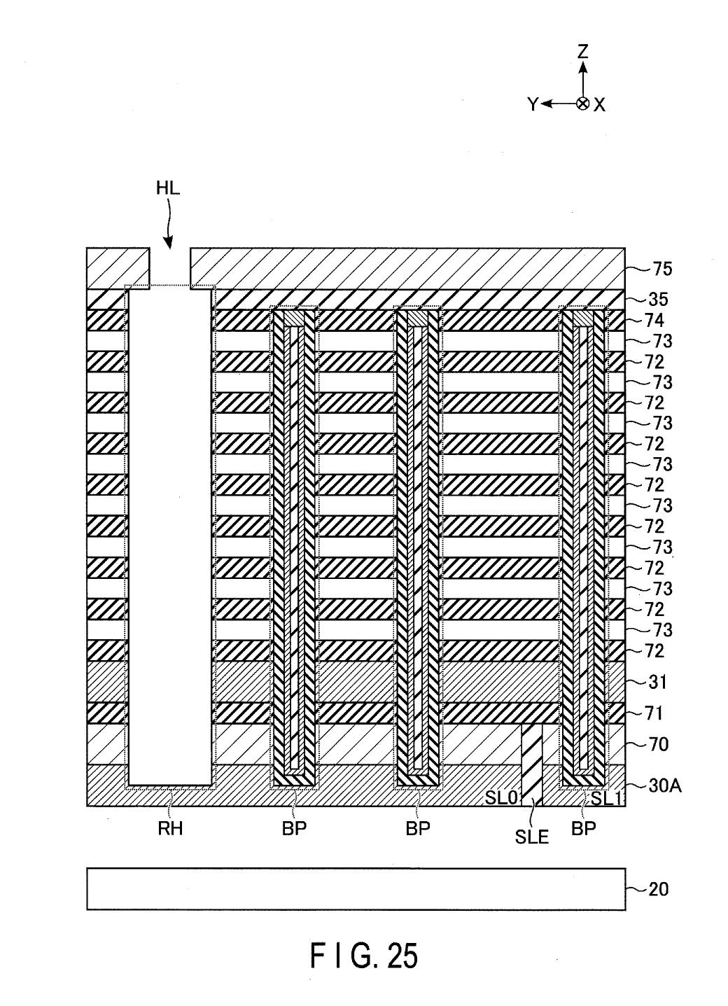

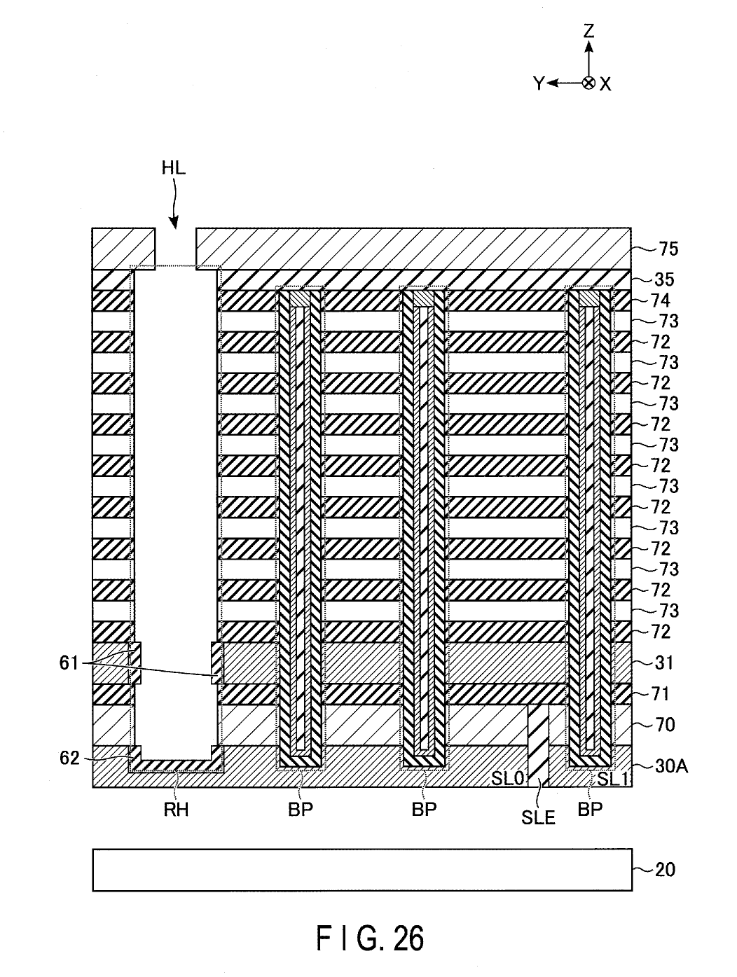

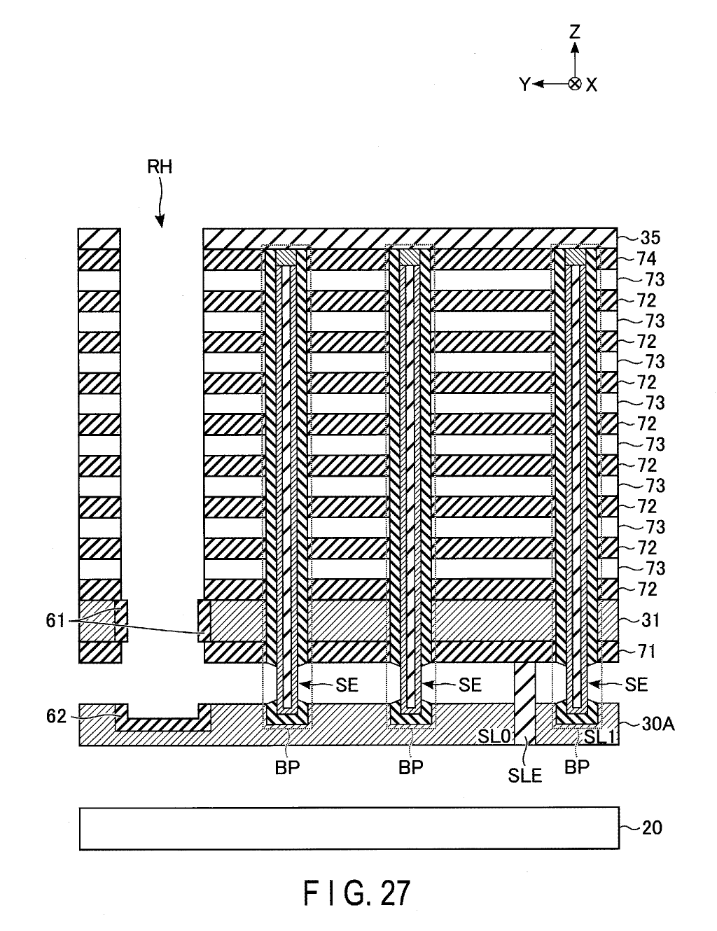

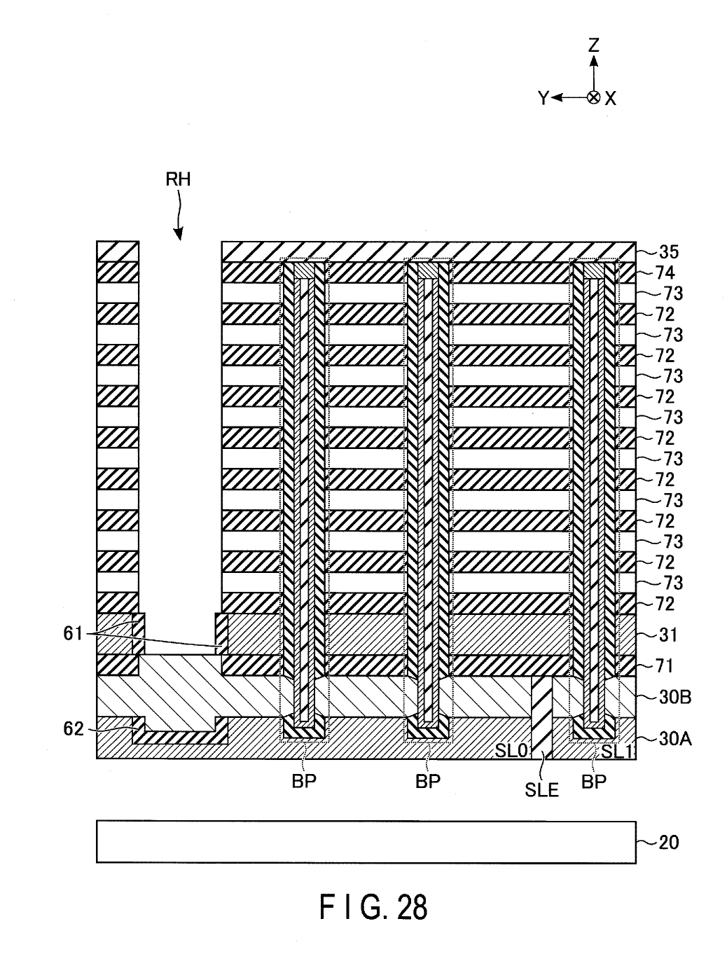

Then, as shown in FIG. 25, each of the core member 40, the semiconductor 41, and the conductor 43, as well as the stacked film 42 formed inside the replace hole RH is removed by a wet etching via each of the plurality of holes HL.

As shown in FIG. 26, the insulation films 62 and 61 are then formed respectively on each of the portions of the conductors 30A and 31 that is exposed to the inside of the replace hole RH.

Specifically, each of the conductors 30A and 31 is selectively oxidized via the replace hole RH. For example, each of the conductors 30A and 31 is oxidized by selectively oxidizing the phosphor-doped polysilicon.

Inside the replace hole RH, the insulation film 62 is formed on an exposed portion of the conductor 30A, and the insulation film 61 is formed on an exposed portion of the conductor 31.

Then, as shown in FIG. 27, each of the sacrifice member 70 and the stacked film 42 of a layer on which the sacrifice member 70 is formed is removed.

Specifically, the sacrifice member 70 is removed by a wet etching via the replace hole RH, and a part of the side surface of the bottom pillar BP is exposed. In the wet etching in the present process, a condition in which the stacked film 42 can also be etched is used.

Therefore, the side surface of the bottom pillar BP is also etched via the replace hole RH and the region from which the sacrifice member 70 has been removed (FIG. 27, “SE”). More specifically, in the layer on which the sacrifice member 70 was formed, the stacked film 42 of the bottom pillar BP is removed, and the semiconductor 41 of the bottom pillar BP is exposed.

Then, in the manner shown in FIG. 28, the conductor 30B is formed.

Specifically, for example, the polysilicon provided as the conductor 30A is selectively grown by Chemical Vapor Deposition (CVD).

In this manner, the conductor 30B is respectively formed in a space in which the sacrifice member 70 was formed, and a space from which the stacked film 42 of the bottom pillar BP was removed. In the present process, the conductor 30B may intrude inside the replace hole RH.

Then, in the manner shown in FIG. 29, each of the plurality of replacement members 73 is replaced by the conductor 32.

Specifically, first the plurality of replacement members 73 are removed by a wet etching via the replace hole RH.

The conductor 32 is then formed in each of the spaces from which each of the plurality of replacement members 73 was removed, and the conductor 32 formed on the side wall of the replace hole RH is removed by, for example, the wet etching. In this manner, the formed conductor 32 is divided, and each of the divided conductors 32 functions as the word line WL.

Then, as shown in FIG. 30, the insulator 60 is formed inside the replace hole RH.

Specifically, for example, the insulator 60 is embedded inside the replace hole RH by the CVD, and the insulator 60 formed on the protective film 35 is removed by an etch back. By the present process, the structure of the replacement pillars RP explained using FIG. 10 is completed.

By the manufacturing process explained above, each of the plurality of source lines SL, the plurality of selection gate lines SGS, the plurality of word lines WL, the plurality of memory pillars MP, and the plurality of replacement pillars RP is formed.

After the manufacturing process explained above, the conductor 33 is formed by, for example, sputtering. The method of forming the conductor 33 is not limited to this, and other methods may also be applied.

For example, in the case where the memory cell array 10 has a structure in which the replacement pillar RP passes through (penetrates) the conductor 33, the conductor 33 may be formed by being replaced in the same manner as the conductor 32.

Specifically, for example, in a process in which the insulation film 72 and the replacement member 73 are alternately stacked on the conductor 31, the replacement member 73 corresponding to the conductor 33 is formed. The process in which the replacement member 73 corresponding to the conductor 33 is formed is not limited to this, as long as the process is prior to the process of replacing the replacement member 73 with the conductor.

Subsequently, for example, the replacement member 73 corresponding to the conductor 33 is removed by the same process as the process for removing the replacement member 73 corresponding to the conductor 32, and the conductor 33 is formed in the space from which the replacement member 73 has been removed.

The manufacturing process explained above is only an example; therefore, other processing may be inserted in between each of the manufacturing processes.

[1-3] Operation of Semiconductor Memory 1

Hereinafter, detailed operations of each of a read operation, a write operation, and an erase operation of the semiconductor memory 1 of the first embodiment will be explained in order.

In the following explanation, the selected and non-selected source lines SL will each be referred to as source lines SLsel and SLusel. The selected and non-selected selection gate lines SGD will each be referred to as selection gate lines SGDsel and SGDusel. The selected and non-selected word lines WL will each be referred to as word lines WLsel and WLusel.

Furthermore, in the following explanation, the voltage of various wirings in a state prior to the execution of various operations is assumed as being a ground voltage VSS. A voltage is assumed as being applied to each of the source lines SL and the selection gate lines SGD by the voltage generation circuit VG and the row decoder module 15. A voltage is assumed as being applied to each of the selection gate line SGS and the word lines WL by the voltage generation circuit VG. A voltage is assumed as being applied to a bit line BL by the sense amplifier unit SAU.

[1-3-1] Read Operation

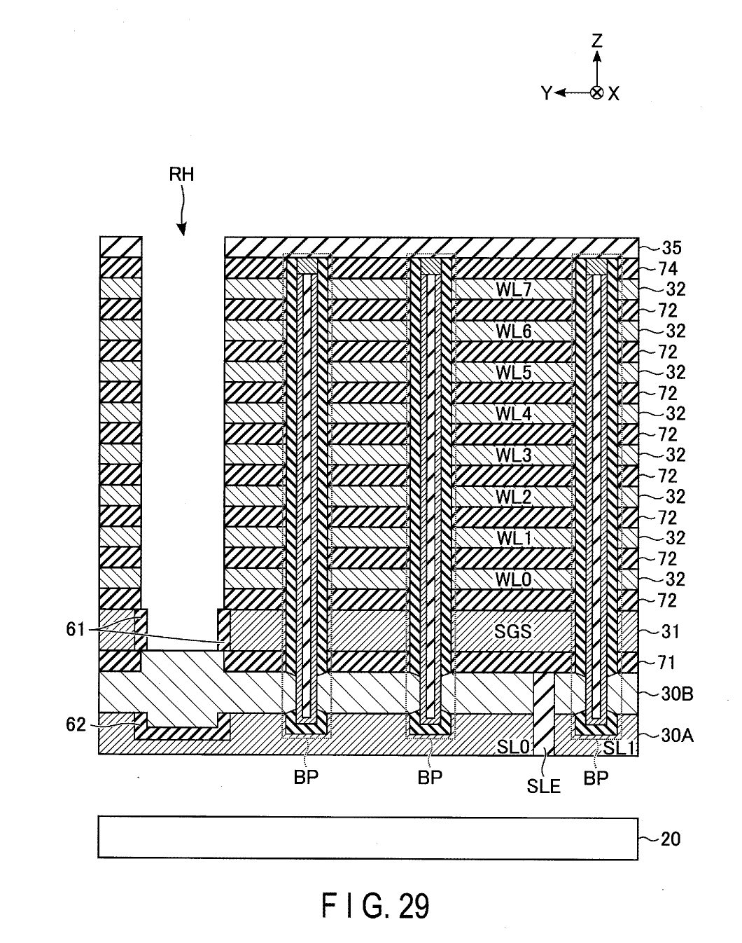

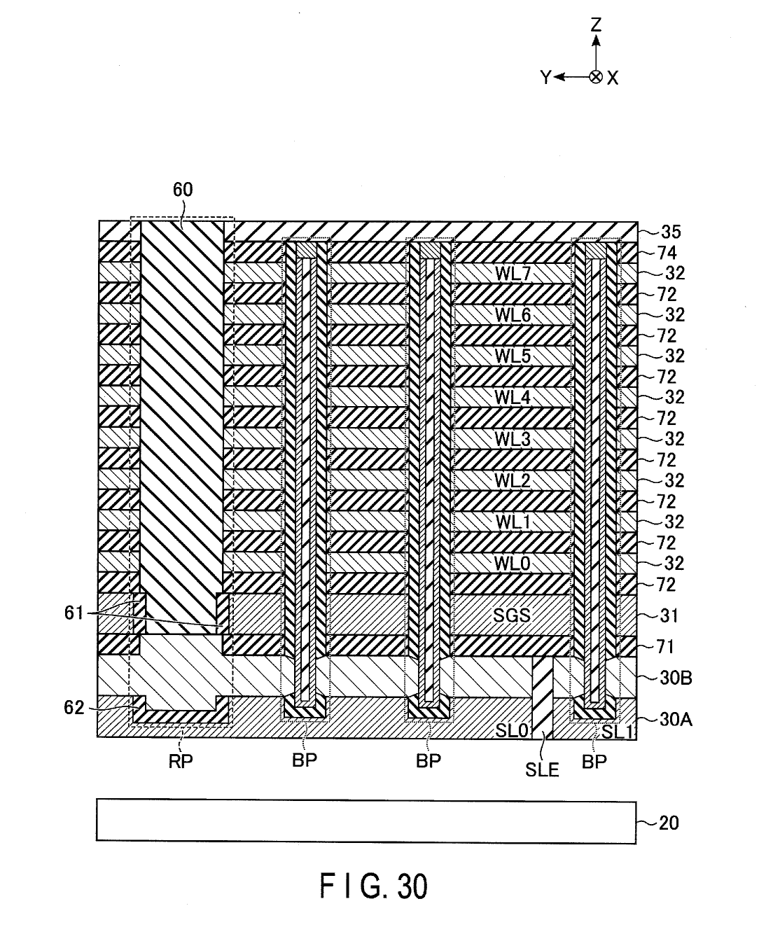

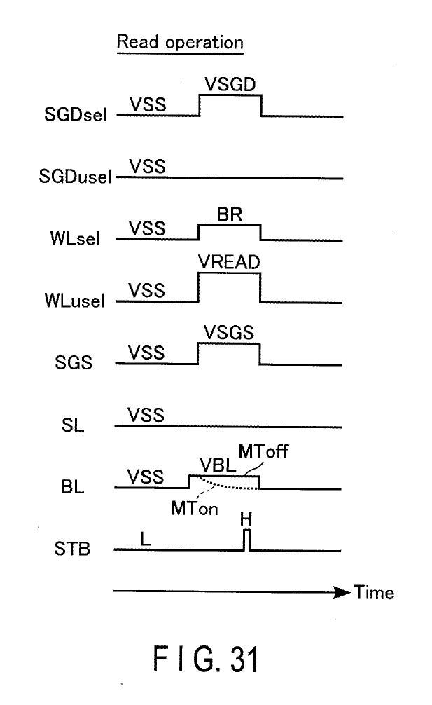

FIG. 31 is a timing chart showing an example of a read operation of the semiconductor memory 1, and exemplifies an operation in the case where the semiconductor memory 1 reads lower page data that is stored in a certain cell unit CU.

As shown in FIG. 31, in the read operation, a voltage VBL is applied to the bit line BL. The value of the voltage VBL is higher than the ground voltage VSS.

A voltage VSGD is applied to the selection gate line SGDsel in a selected block BLK. The value of the voltage VSGD is higher than the ground voltage VSS. The selection transistor ST1 to which the voltage VSGD is applied to its gate comes to be in an ON-state.

The ground voltage VSS, for example, is applied to the selection gate line SGDusel in the selected block BLK. The selection transistor ST1 to which the ground voltage VSS is applied to its gate comes to be in an OFF-state. As for each of the selection gate lines SGD1 and SGD2 in the non-selected block BLK, for example, a voltage that is the same as that applied to the selection gate line SGDusel is applied (not shown).

A voltage VSGS is applied to the selection gate line SGS. The value of the voltage VSGS is higher than the ground voltage VSS. In the selected block. BLK, the selection transistor ST2 to which the voltage VSGS is applied to its gate comes to be in an ON-state.

Regardless of whether it is a selected block BLK or a non-selected block BLK, the ground voltage VSS, for example, is applied to the source line SL. Each source line SL in the read operation is not limited to this, and may be grounded.

The read voltage BR, for example, is applied to the word line WLsel. In the selected block BLK, the memory cell transistor MT connected to the word line WLsel comes to be in an ON-state or an OFF-state based on the held data.

A read pass voltage VREAD is applied to the word line WLusel. In the selected block BLK, the memory cell transistor MT connected to the word line WLusel comes to be in an ON-state regardless of the held data.

In the manner above, a voltage is applied to each of the selection gate lines SGDsel, SGDusel, and SGS, the word lines WLsel and WLusel, and the source line SL. The voltage of the bit line BL then changes based on, for example, the state of the memory cell transistor MT connected to the selection word line WLsel in the selected blocks BLK.

Specifically, in the case where the memory cell transistor MT connected to the selection word line WLsel in the selected block BLK is in an ON-state, a voltage of a corresponding bit line BL drops (MTon). On the other hand, in the case where the memory cell transistor MT connected to the selection word line WLsel is in an OFF-state, the voltage of the corresponding bit line BL is maintained at VBL (MToff).

After the voltage of the bit line BL is sufficiently changed, the sequencer 13 asserts the control signal STB. Each of the sense amplifier units SAU then determines data held in the memory cell transistor MT based on the voltage of the corresponding bit line BL.

This determination result is held in one of the latch circuits inside the sense amplifier unit SAU. The sequencer 13 controls each of the sense amplifier units SAU and outputs the determination result held in the latch circuit to the memory controller 2 as read data of the lower page.

In the above manner, the semiconductor memory 1 is capable of reading the lower page data. The explanation of the read operation of the upper page data will be omitted since the read operation of the upper page data is the same as the read operation of the lower page data except that the read voltage to be used is changed, and that computation processing of each of the determination results according to a plurality of read voltages is added.

In the above explanation, the read operation of the semiconductor memory 1 is exemplified regarding a case in which each of the cell units CU stores two-page data; however, the read operation of the semiconductor memory 1 is not limited to this. For example, even in the case where each of the cell units CU stores one-page data or page data equal to or more than three-page data, the semiconductor memory 1 can execute the same read operation by changing the read voltage and the computation processing, etc. as appropriate.

Furthermore, in the read operation explained by using FIG. 31, an example in the case of changing the voltage of the bit line BL after applying a read voltage to the word line WLsel is explained; however, the read operation is not limited to this. For example, depending on the circuit configuration of the sense amplifier unit SAU, in some cases, the voltage of the bit line BL may not vary after the read voltage is applied to the word line WLsel.

[1-3-2] Write Operation

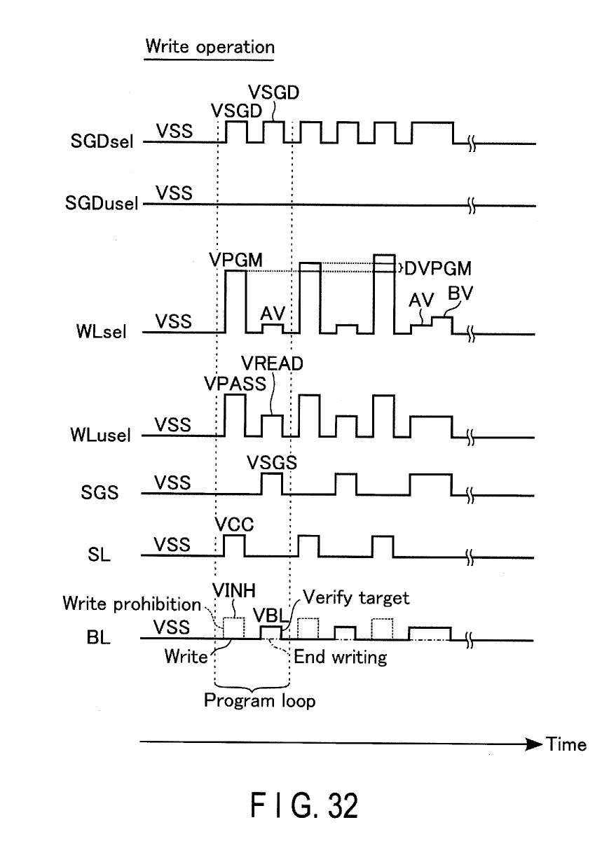

FIG. 32 is a timing chart showing an example of a write operation of the semiconductor memory 1, and exemplifies an operation in the case where the semiconductor memory 1 writes two-page data to a certain cell unit CU.

As shown in FIG. 32, in the write operation, the sequencer 13 of the semiconductor memory 1 repeatedly executes a program loop. Each of the program loops includes a program operation and a verify operation.

In the following, first, an initial program loop shown in FIG. 32 will be referred to explain details of the program operation and the verify operation in sequence.

The program operation is an operation for increasing a threshold voltage of the memory cell transistor MT.

Specifically, in the program operation, a ground voltage VSS is applied to a write target bit line BL, that is, a bit line BL connected to a memory cell transistor MT whose threshold voltage is to be increased by the program operation (FIG. 32, “write”).

A voltage VINH is applied to a write-inhibited bit line BL, that is, a bit line BL connected to a memory cell transistor MT whose threshold voltage is suppressed from increasing by the program operation.

The voltage VSGD is applied to the selection gate line SGDsel in the selected block BLK. Among the selection transistors ST1 of which the voltage VSGD is applied to its gate, the selection transistor ST1 that is connected to the write target bit line. BL comes to be in an ON-state, and the selection transistor ST1 that is connected to the write-inhibited bit line BL comes to be in an OFF-state.

The ground voltage VSS, for example, is applied to the selection gate line SGDusel in the selected block BLK. The selection transistor ST1 of which the ground voltage VSS is applied to its gate comes to be in an OFF-state. As for each of the selection gate lines SGD1 and SGD2 in the non-selected block BLK, for example, a voltage that is the same as that applied to the selection gate line SGDusel is applied (not shown).

The voltage VSS is applied to the selection gate line SGS. In each of the selected block BLK and the non-selected block BLK, the selection transistor ST2 to which the voltage VSS is applied to its gate comes to be in an OFF-state.

Regardless of whether it is a selected block BLK or a non-selected block BLK, a voltage VCC, for example, is applied to the source line SL. The value of the voltage VCC is higher than the ground voltage VSS. By applying the voltage VCC to the source line SL, since a source voltage of the selection transistor ST2 becomes higher than a gate voltage, the selection transistor ST2 is further suppressed from coming to be in an ON-state.

In the manner above, a voltage is applied to each of the selection gate lines SGDsel, SGDusel, and SGS, and the source line SL.

In a NAND string NS that is connected to the write-inhibited bit line BL in the selected block BLK, since each of the selection transistors ST1 and ST2 comes to be in an OFF-state, a channel comes to be in a floating state. In the same manner, in a NAND string NS in the non-selected block BLK, a channel comes to be in a floating state.

A write pass voltage VPASS is applied to the word line WLusel. In the selected block BLK, a memory cell transistor MT that is connected to each of the word line WLusel and the write target bit line BL comes to be in an ON-state. Therefore, in the selected block BLK, a channel voltage of the NAND string NS that is connected to the write target bit line BL is, for example, fixed to the ground voltage VSS.

On the other hand, a channel voltage of the NAND string NS in the floating state increases with the application of the write pass voltage VPASS to the word line WLusel. An operation to increase the channel voltage of the NAND string NS in this manner is referred to as, for example, a self-boost technique.

A program voltage VPGM is then applied to the word line WLsel. The value of the program voltage VPGM is higher than the write pass voltage VPASS. When the program voltage VPGM is applied to the word line WLsel, in the memory cell transistor MT that is connected to each of the word line WLsel and the write target bit line BL, electrons are injected into the charge storage layer (for example, the insulation film 45) by a voltage difference between the channel and the control gate, thereby increasing the threshold voltage.

On the other hand, as for each of the memory cell transistor MT connected to each of the word line WLsel and the write-inhibited bit line SL, and the memory cell transistor MT connected to the word line WLsel in the non-selected block BLK, since the potential difference between the channel voltage in the floating state and the control gate is small, the increase in the threshold voltage is suppressed.

A series of operations explained above corresponds to the program operation. After the program operation is ended, the sequencer 13 continuously moves on to the verify operation.

The verify operation is a read operation for determining whether or not the memory cell transistor MT has reached a desired threshold voltage.

In the verify operation, a write level to be verified for each sense amplifier unit SAU is determined based on the write data. In the verify operation, the memory cell transistor MT that has been confirmed as reaching a desired threshold voltage is determined as passing the verification of such level.

Specifically, in the verify operation, for example, a verify voltage AV is applied to the word line WLsel.

A voltage VBL is applied to a bit line BL that is connected to a memory cell transistor MT that has not passed the verification (FIG. 32, “verify target”).

The voltage VSS, for example, is applied to each of the bit line BL connected to the memory cell transistor MT that has passed the verification and the bit line BL connected to the write-inhibited memory cell transistor MT (FIG. 32, “end writing”).

Since a voltage to be applied to each of the selection gate lines SGD and SGS, the word line WLusel, and the source line SL is the same as the read operation explained by using FIG. 31, the explanation will be omitted.

Each of the sense amplifier units SAU determines whether or not the threshold voltage of the memory cell transistor MT connected to the word line WLsel exceeds the verify voltage AV based on a voltage of a corresponding bit line BL.

A memory cell transistor MT to which “A” level data is written is determined as passing verification in the case where the threshold voltage exceeds the verify voltage AV, and a corresponding sense amplifier unit SAU is set to write inhibition in the subsequent program loops.

A series of operations explained above corresponds to the verify operation.

When a set of the program operation and the verify operation (program loop) is ended, the sequencer 13 steps up the program voltage VPGM, and repeatedly executes the same program loop. A step-up width DVPGM of the program voltage VPGM may be set to any value.

A verify level executed by the verify operation may be changed as appropriate. For example, the sequencer 13 changes the type and the numbers of verify voltage to be used as the program loop is repeated.

In an example shown in FIG. 32, the sequencer 13 executes an “A” level verification in the verify operation of the first and second program loops, and continuously executes each of the “A” level and “B” level verifications in the verify operation of the third program loop.

When the sequencer 13 senses that the number of memory cell transistors MT that has passed verification of a certain level exceeds a predetermined number in the program loop, data writing corresponding to such level is considered as being completed. When the sequencer 13 senses, for example, that all levels of writing have been completed, the write operation is ended.

[1-3-3] Erase Operation

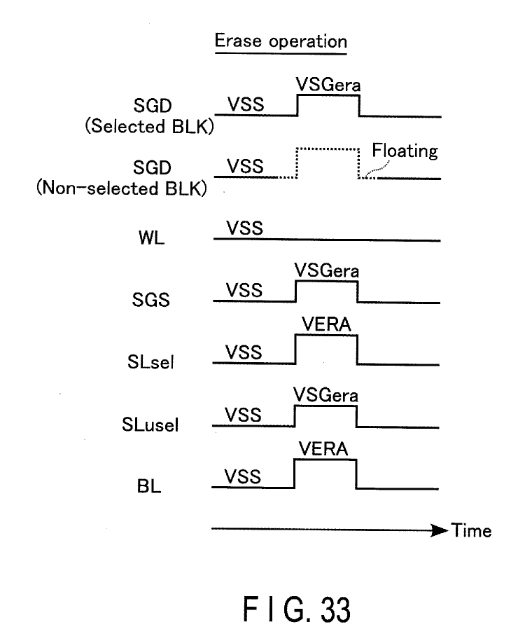

FIG. 33 is a timing chart showing an example of an erase operation of the semiconductor memory 1, and exemplifies an operation in the case where the semiconductor memory 1 erases data stored in a certain block BLK.

The sequencer 13 during an erase operation is assumed as setting a voltage of the control signal BLS to level “L”. The transistor T13 of which the level “L” signal is input to its gate comes to be in an OFF-state. In other words, during the erase operation explained below, each of the sense amplifier units SAU and the bit line BL are electrically disconnected.

As shown in FIG. 33, in the erase operation, the selection gate line SGD of the non-selected block BLK is in a floating state.

Specifically, the sequencer 13, for example, sets the voltage of the control signal S2 to level “L” so that the transistor T2 comes to be in an OFF-state. The signal line SGDDusel then comes to be in a floating state, and the selection gate line SGD that is electrically connected to the signal line SGDDusel in the non-selected block BLK also comes to be in a floating state. The selection gate line SGD of the non-selected block BLK is not limited to this, and may come to be in a floating state by the control of the row decoder RD.

A voltage VSGera is applied to each of the selection gate lines SGD in the selected block BLK. The value of the voltage VSGera is higher than the ground voltage VSS. In the selected block BLK, the selection transistor ST1 of which the voltage VSGera is applied to its gate comes to be in an ON-state.

Each of the selection gate lines SGD of the non-selected block BLK comes to be, for example, in a floating state after the ground voltage VSS is applied. Therefore, each of the selection transistors ST1 in the non-selected block BLK is in an OFF-state.

The voltage VSGera is applied to the selection gate line SGS. In the selected block BLK, the selection transistor ST2 of which the voltage VSGera is applied to its gate comes to be in an ON-state.

The ground voltage VSS, for example, is applied to each of the word lines WL.

The voltage VSGera is applied to the source line SLusel. Therefore, in the non-selected block BLK, the source voltage and the gate voltage of the selection transistor ST2 become almost the same, and the selection transistor ST2 comes to be in an OFF-state.

In the above manner, a voltage is applied respectively to the selection gate line SGD of the selected block BLK, the selection gate line SGS, each of the word lines WL, and the non-selected source line SLusel.

Then, in the NAND string NS in the non-selected block BLK, since each of the selection transistors ST1 and ST2 are in an OFF-state, the channel comes to be in a floating state.

Subsequently, a voltage VERA is applied to the source line SLsel. The value of the voltage VERA is higher than the voltage VSGera.

The channel voltage of the NAND string NS in the selected block BLK then rises up to the voltage VERA along with the application of the voltage VERA to the source line SLsel.

At this time, the voltage of each bit line BL rises up to the voltage VERA along with the rise in the channel voltage of the NAND string NS in the selected block BLK. Since the selection gate line SGD in the non-selected block BLK is in a floating state, the voltage of the selection gate line SGD rises along with the rise in the voltage of each of the bit lines BL.

When the channel voltage of the NAND string NS in the selected block BLK rises up to the VERA, the channel voltage becomes higher than the voltage of the control gate in the memory cell transistor MT included in the block BLK.

As a result, in the memory transistor MT in the selected block BLK, the electrons are drawn from the charge storage layer (for example, the insulation film 45) by a potential difference between the channel and the control gate, and the threshold voltage drops down to the “ER” level.

In the above manner, the semiconductor memory 1 is capable of erasing data stored in the memory cell transistor MT in the block BLK.

In the erase operation explained above, the voltage VSGera that is applied to each of the selection gate lines SGD and SGS and the source line SLusel may be different. The voltage applied respectively to the selection gate lines SGD and SGS and the source line SLusel is set at least in a manner to be able to realize the above operation.

[1-4] Advantageous Effects of First Embodiment

According to the semiconductor memory 1 of the first embodiment explained above, a chip area can be reduced. Hereinafter, the present effect will be explained in detail.

In the manufacturing process of a semiconductor memory device in which memory cells are stacked three-dimensionally, a stacked wiring that is connected to each gate of the NAND string NS is formed, for example, by forming a stacked body in which a replacement member and an insulation film are alternately stacked, then replacing the replacement member with a conductor. As a method of replacing the replacement member with the conductor, for example, a manufacturing method is known in which a slit for sectioning the blocks BLK is formed, and removal of the replacement member and formation of the conductor are executed via the slit.

In contrast, in the semiconductor memory 1 of the first embodiment, a slit used for removing the replacement member and forming the conductor is not formed. Instead, in the semiconductor memory 1 of the first embodiment, a plurality of replace holes RH are formed in the memory region MR of the memory cell array 10.

The plurality of replace holes RH are used in the same manner as the above-mentioned slit used for removing the replacement member and forming the conductor. Specifically, as explained using FIG. 17 to FIG. 30, the semiconductor memory 1 of the first embodiment removes the replacement member 73 via the replace hole RH, and forms the conductor 32 in a region from which the replacement member 73 has been removed.

In the above manner, the semiconductor memory 1 of the first embodiment is capable of replacing the replacement member 73 with the conductor 32 by using the plurality of replace holes RH, and forming the stacked wiring that is connected to each gate of the NAND string NS.

The conductor 32 (word line) formed in the above manner becomes a shape that is continuous between the blocks BLK in the corresponding wiring layer. That is, in the case where a slit extended in the X-direction is formed, a word line is divided by dividing the word line by the slit in the Y-direction, whereas, in the semiconductor memory 1 of the first embodiment, the word line WL is not structured to be divided in the Y-direction.

In this case, the word line WL would not be able to carry out control in units of the blocks BLK; however, in the semiconductor memory 1 of the first embodiment, instead of dividing the word line WL, the conductor 30 (source line SL) is divided. In the semiconductor memory 1 of the first embodiment, each of the divided source lines SL is configured to be independently controllable, and each of the configurations corresponding to the divided source lines SL is used as the block BLK.

This allows the semiconductor memory 1 of the first embodiment to execute the read operation, the write operation, and the erase operation in units of blocks BLK, in the same manner as the semiconductor memory device in which the word lines are divided.

As a result, in the semiconductor memory 1 of the first embodiment, the area of the memory cell array 10 can be reduced in lieu of the omitted slit. Accordingly, the semiconductor memory 1 of the first embodiment is capable of reducing the chip area since the area of the memory cell array 10 is designed small.

[1-5] Modified Example of First Embodiment

In the first embodiment, the replacement pillars RP in the memory region MR of the memory cell array 10 may be arranged otherwise.

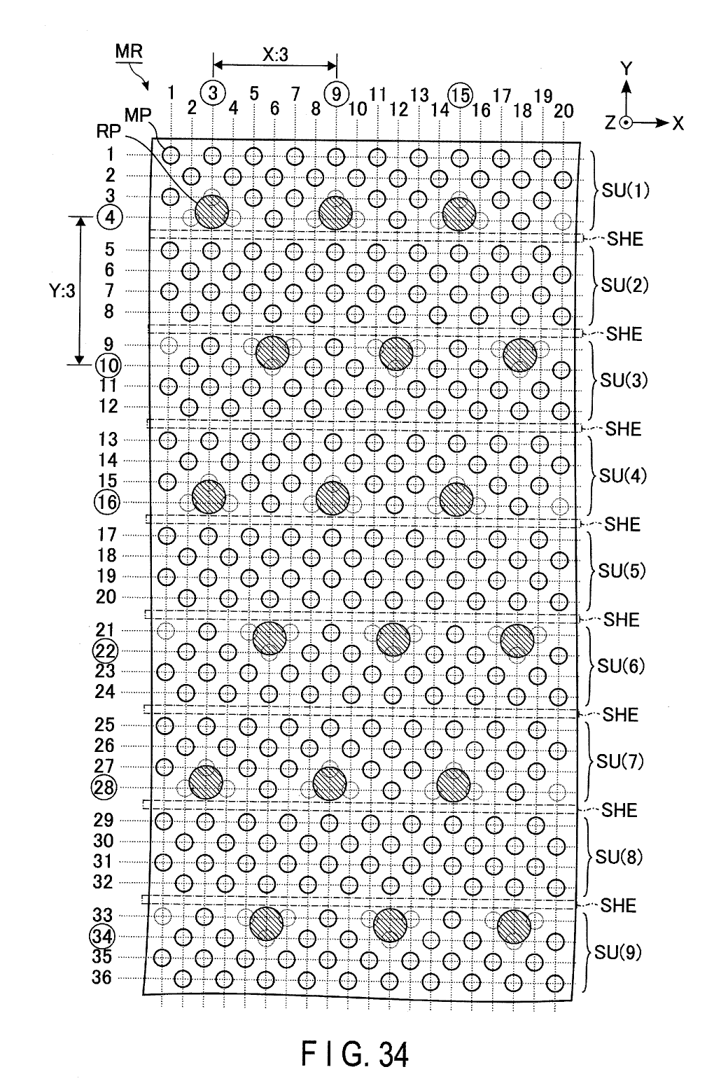

FIG. 34 to FIG. 38 each show an example of a plan layout of a memory cell array 10 in first to fifth modified examples of the first embodiment, and extract and show nine string units SU (1) to (9) that are arranged along the Y-direction in the memory cell array 10.

In the plan layout of the memory cell array 10 in a memory region MR referred to in the following explanation, a slit SLE being a border of blocks BLK is omitted. Furthermore, the arrangement of the slit SLE may be changed as appropriate based on the number of string units SU included in one block BLK.

As in a first modified example of the first embodiment shown in FIG. 34, a plurality of replacement pillars RP may be arranged respectively at a position where the X-coordinate is “6×i+3” (i is an integer equal to or greater than 0) and the Y-coordinate is “12×j+4” (j is an integer equal to or greater than 0), and at a position where the X-coordinate is “6×i+6” and the Y-coordinate is “12×j+10”.

In this case, the number of memory pillars MP where the Y-coordinate is an even number (for example, Y-coordinate “2”) and is arranged along the X-direction between the X-coordinates (for example, X-coordinates “4” to “8”) of the replacement pillars RP neighboring in the X-direction becomes three (FIG. 34, X:3).

Furthermore, the number of memory pillars MP where the X-coordinate is an odd number (for example, X-coordinate “3”) and is arranged along the Y-direction between the Y-coordinates (for example, Y-coordinates “5” to “9”) of the replacement pillars RP neighboring in a direction that intersects each of the X-direction and the Y-direction becomes three (FIG. 34, Y:3).

In other words, the number of memory pillars MP where the X-coordinate is an odd number (for example, X-coordinate “5”) and is arranged along the Y-direction between the Y-coordinates (for example, Y-coordinates “5” to “15”) of the replacement pillars RP neighboring in the Y-direction becomes six.

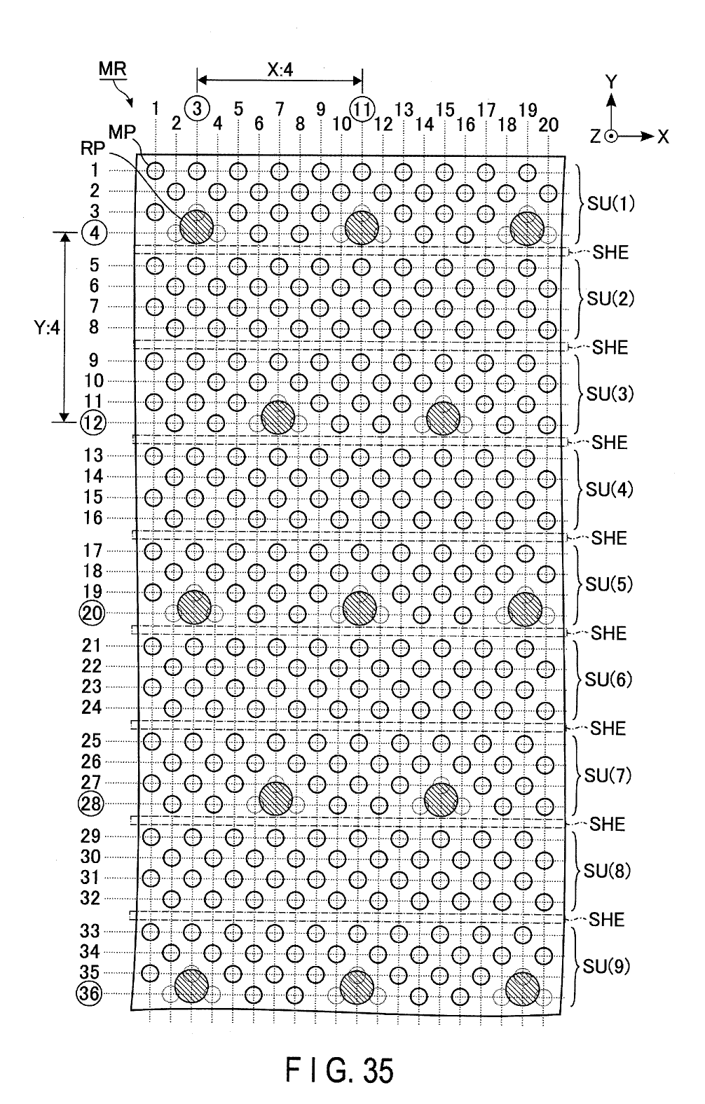

As in a second modified example of the first embodiment shown in FIG. 35, a plurality of replacement pillars RP may be arranged respectively at a position where the X-coordinate is “8×i+3” and the Y-coordinate is “16×j+4”, and at a position where the X-coordinate is “8×i+7” and the Y-coordinate is “16×j+12”.

In this case, the number of memory pillars MP where the Y-coordinate is an even number (for example, Y-coordinate “2”) and is arranged along the X-direction between the X-coordinates (for example, X-coordinates “4” to “10”) of the replacement pillars RP neighboring in the X-direction becomes four (FIG. 35, X:4).

Furthermore, the number of memory pillars MP where the X-coordinate is an odd number (for example, X-coordinate “3”) and is arranged along the Y-direction between the Y-coordinates (for example, Y-coordinates “5” to “11”) of the replacement pillars RP neighboring in a direction that intersects each of the X-direction and the Y-direction becomes four (FIG. 35, Y:4).

In other words, the number of memory pillars MP where the X-coordinate is an odd number (for example, X-coordinate “5”) and is arranged along the Y-direction between the Y-coordinates (for example, Y-coordinates “5” to “19”) of the replacement pillars RP neighboring in the Y-direction becomes eight.

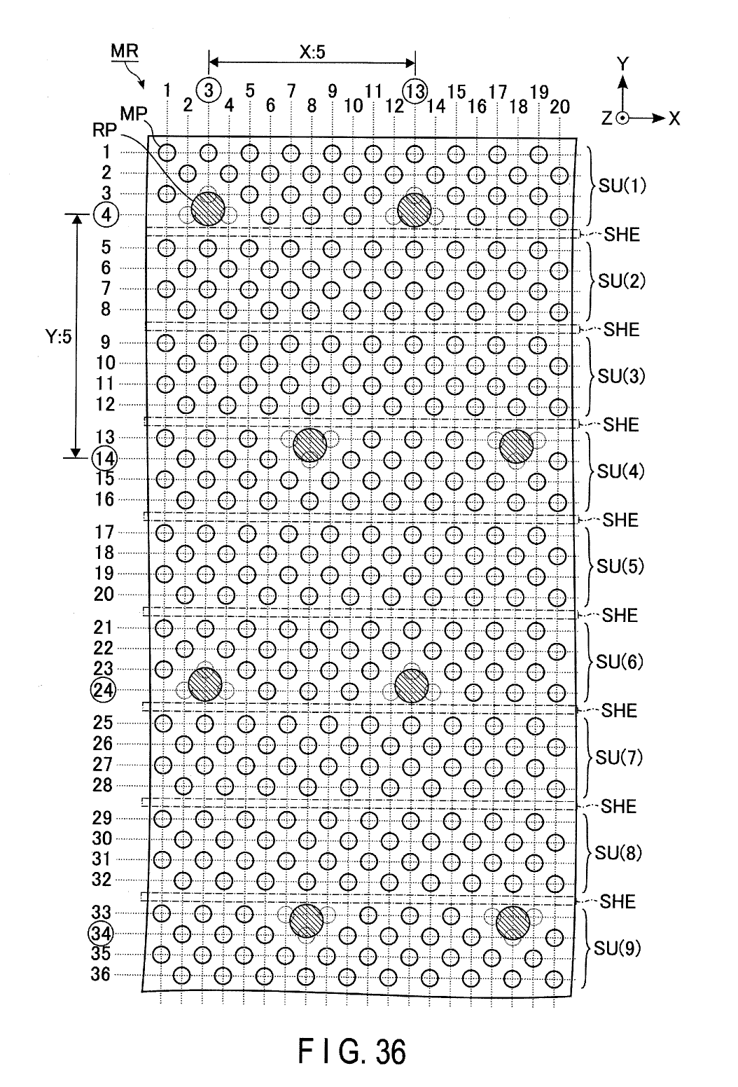

As in a third modified example of the first embodiment shown in FIG. 36, a plurality of replacement pillars RP may be arranged respectively at a position where the X-coordinate is “10×i+3” and the Y-coordinate is “20×j+4”, and at a position where the X-coordinate is “10×i+8” and the Y-coordinate is “20×j+14”.

In this case, the number of memory pillars MP where the Y-coordinate is an even number (for example, Y-coordinate “2”) and is arranged along the X-direction between the X-coordinates (for example, X-coordinates “4” to “12”) of the replacement pillars RP neighboring in the X-direction becomes five (FIG. 36, X:5).

Furthermore, the number of memory pillars MP where the X-coordinate is an odd number (for example, X-coordinate “3”) and is arranged along the Y-direction between the Y-coordinates (for example, Y-coordinates “5” to “13”) of the replacement pillars RP neighboring in a direction that intersects each of the X-direction and the Y-direction becomes five (FIG. 36, Y:5).

In other words, the number of memory pillars MP where the X-coordinate is an odd number (for example, X-coordinate “5”) and is arranged along the Y-direction between the Y-coordinates (for example, Y-coordinates “5” to “23”) of the replacement pillars RP neighboring in the Y-direction becomes ten.

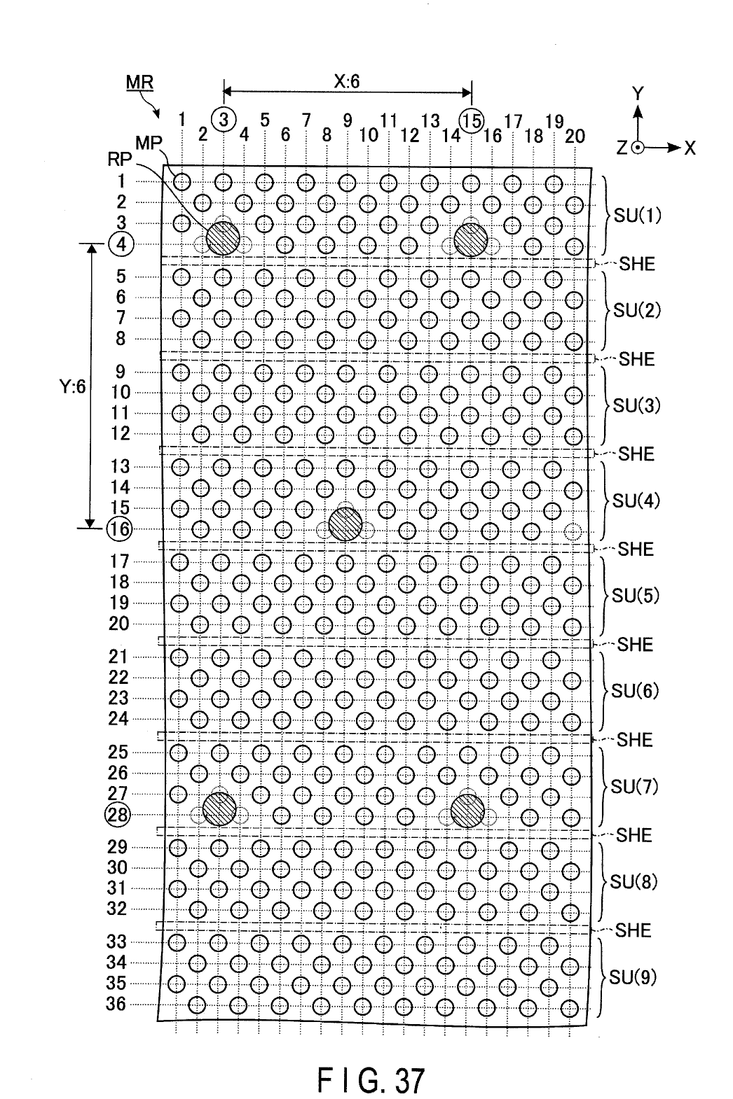

As in a fourth modified example of the first embodiment shown in FIG. 37, a plurality of replacement pillars RP may be arranged respectively at a position where the X-coordinate is “12×i+3” and the Y-coordinate is “24×j+4”, and at a position where the X-coordinate is “12×i+9” and the Y-coordinate is “24×j+16”.

In this case, the number of memory pillars MP where the Y-coordinate is an even number (for example, Y-coordinate “2”) and is arranged along the X-direction between the X-coordinates (for example, X-coordinates “4” to “14”) of the replacement pillars RP neighboring in the X-direction becomes six (FIG. 37, X:6).

Furthermore, the number of memory pillars MP where the X-coordinate is an odd number (for example, X-coordinate “3”) and is arranged along the Y-direction between the Y-coordinates (for example, Y-coordinates “5” to “15”) of the replacement pillars RP neighboring in a direction that intersects each of the X-direction and the Y-direction becomes six (FIG. 37, Y:6).

In other words, the number of memory pillars MP where the X-coordinate is an odd number (for example, X-coordinate “5”) and is arranged along the Y-direction between the Y-coordinates (for example, Y-coordinates “5” to “27”) of the replacement pillars RP neighboring in the Y-direction becomes twelve.

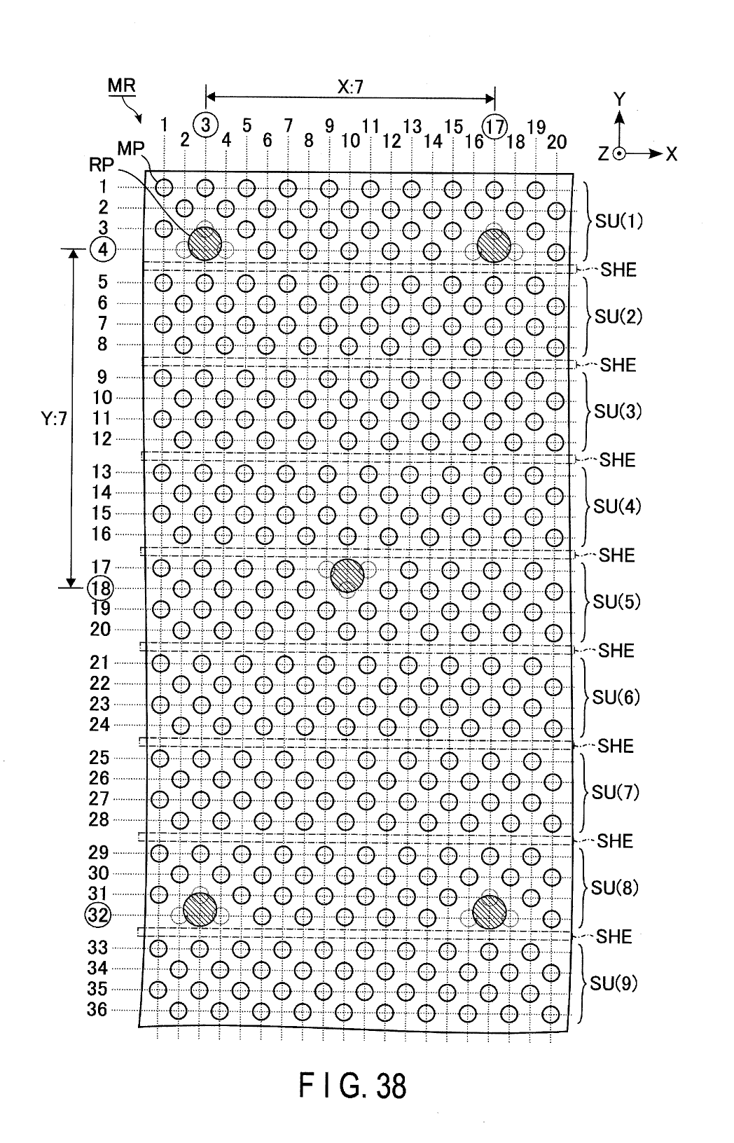

As in a fifth modified example of the first embodiment shown in FIG. 38, a plurality of replacement pillars RP may be arranged respectively at a position where the X-coordinate is “14×i+3” and the Y-coordinate is “28×j+4”, and at a position where the X-coordinate is “14×i+10” and the Y-coordinate is “28×j+18”.

In this case, the number of memory pillars MP where the Y-coordinate is an even number (for example, Y-coordinate “2”) and is arranged along the X-direction between the X-coordinates (for example, X-coordinates “4” to “16”) of the replacement pillars RP neighboring in the X-direction becomes seven (FIG. 38, X:7).

Furthermore, the number of memory pillars MP where the X-coordinate is an odd number (for example, X-coordinate “3”) and is arranged along the Y-direction between the Y-coordinates (for example, Y-coordinates “5” to “17”) of the replacement pillars RP neighboring in a direction that intersects each of the X-direction and the Y-direction becomes seven (FIG. 38, Y:7).

In other words, the number of memory pillars MP where the X-coordinate is an odd number (for example, X-coordinate “5”) and is arranged along the Y-direction between the Y-coordinates (for example, Y-coordinates “5” to “31”) of the replacement pillars RP neighboring in the Y-direction becomes fourteen.

The semiconductor memory 1 is able to obtain the same advantageous effects as in the first embodiment even in the case where any one of the first to fifth modified examples of the first embodiment explained above is adopted.

### [2] Second Embodiment

In a semiconductor memory 1 of a second embodiment, replacement pillars RP are arranged differently from the first embodiment, and the number of memory pillars MP connected to a bit line BL is made uniform. In the following, points that are different from the first embodiment will be explained regarding the semiconductor memory 1 of the second embodiment.

[2-1] Plan Layout of Memory Cell Array 10

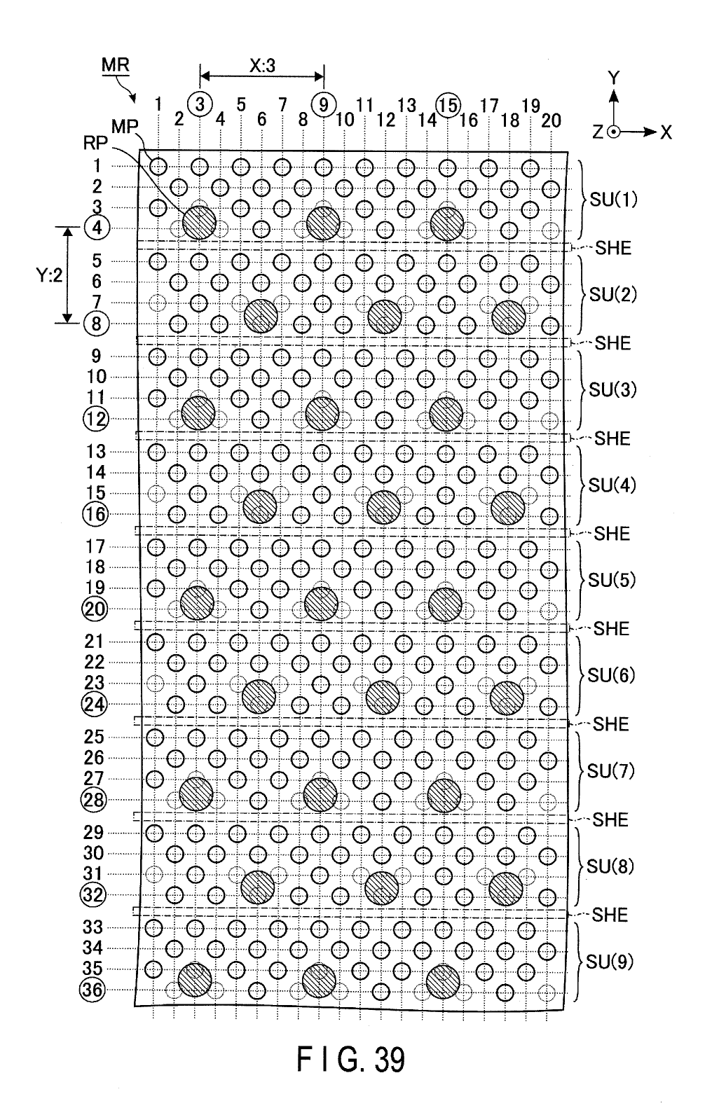

FIG. 39 shows an example of a plan layout of a memory cell array 10 in the second embodiment, and extracts and shows nine string units SU (1) to (9) that are arranged along the Y-direction in the memory cell array 10.

As shown in FIG. 39, a plurality of replacement pillars RP in the second embodiment may be arranged respectively at a position where the X-coordinate is “6×i+3” (i is an integer equal to or greater than 0) and the Y-coordinate is “8×j+4” (j is an integer equal to or greater than 0), and at a position where the X-coordinate is “6×i+6” and the Y-coordinate is “8×j+8”.

That is, in the second embodiment, an interval of the replacement pillars RP neighboring in the X-direction is the same as that in the first modified example of the first embodiment (FIG. 39, X:3). An interval of the replacement pillars RP neighboring in the Y-direction is the same as that in the first embodiment (FIG. 39, Y:2).

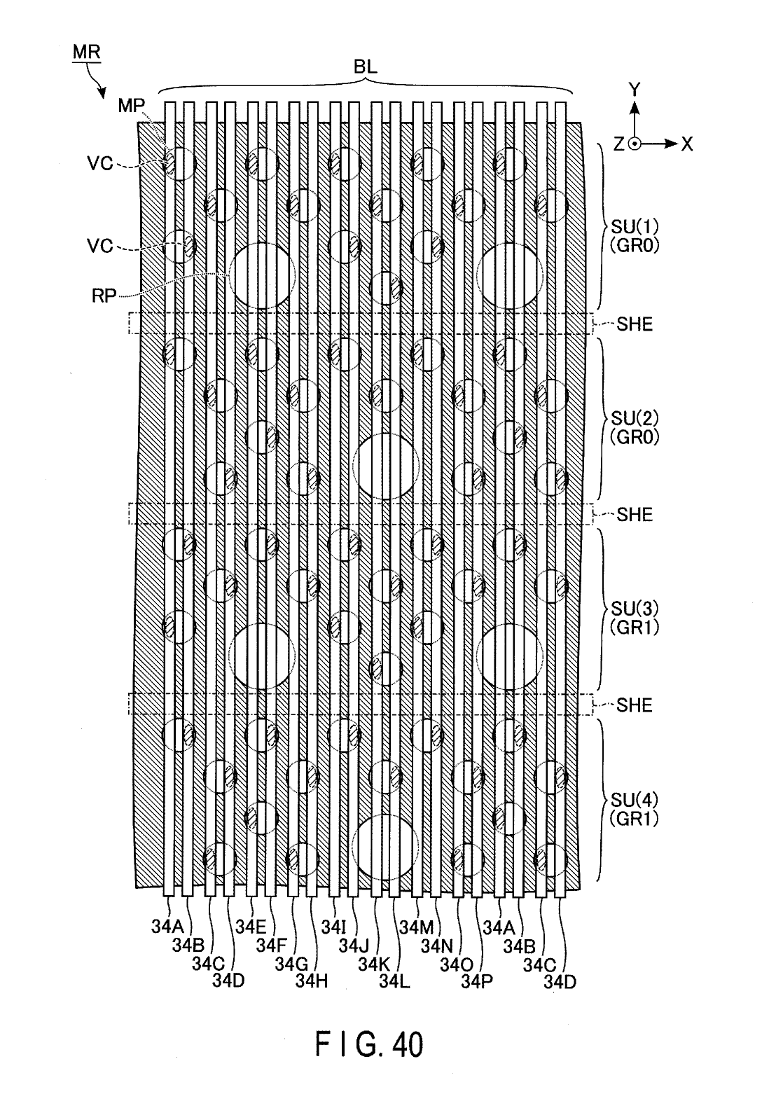

FIG. 40 shows a more detailed example of a plan layout of the memory cell array 10 in a memory region MR, in which four string units SU(1) to (4) are extracted from among a plurality of string units SU included in the memory cell array 10 in the second embodiment.

As shown in FIG. 40, in the memory cell array 10, a plurality of conductors 34 and a plurality of contacts VC are arranged corresponding to the arrangement of the memory pillars MP and the replacement pillars RP in the same manner as explained using FIG. 9.

A connection relationship between the bit line BL and the memory pillar MP is such that, for example, a similar connection relationship is repeated for every sixteen bit lines BL. In FIG. 40, sixteen conductors 34 that correspond to a set of such sixteen bit lines BL are shown respectively as conductors 34A, 34B, 34C, 34D, 34E, 34F, 34G, 34H, 34I, 34J, 34K, 34L, 34M, 34N, 34O, and 34P.

For example, in group GR0 of the string units SU(1) and SU(2), each of the conductors 34A, 34C, 34E, 34G, 34I, 34K, 34M, and 34O is connected to one memory pillar MP in the string unit SU(1) and one memory pillar MP in the string unit SU(2).

Each of the conductors 34B, 34J, 34L, and 34N is connected to one memory pillar MP in the string unit SU(1). Each of the conductors 34D, 34F, 34H, and 34P is connected to one memory pillar MP in the string unit SU(2).

That is, in group GR0, two memory pillars MP are connected to each of the conductors 34A, 34C, 34E, 34G, 34I, 34K, 34M, and 34O, and one memory pillar MP is connected to each of the conductors 34B, 34D, 34F, 34H, 34J, 34L, 34N, and 34P.

On the other hand, in group GR1 of the string units SU(3) and SU(4), each of the conductors 34B, 34D, 34F, 34H, 34J, 34L, 34N, and 34P is connected to one memory pillar MP in the string unit SU(3) and one memory pillar MP in the string unit SU(4).

Each of the conductors 34A, 34I, 34K, and 34M is connected to one memory pillar MP in the string unit SU(3). Each of the conductors 34C, 34E, 34G, and 34O is connected to one memory pillar MP in the string unit SU(4).

That is, in group GR1, one memory pillar MP is connected to each of the conductors 34A, 34C, 34E, 34G, 34I, 34K, 34M, and 34O, and two memory pillars MP are connected to each of the conductors 34B, 34D, 34F, 34H, 34J, 34L, 34N, and 34P.

In the manner mentioned above, the connection relationship between the string units SU of group GR1 is, for example, the same as that obtained by reversing the connection relationship between the string units SU of group GR0. That is, in the combination of groups GR0 and GR1, the number of memory pillars MP connected to each of the conductors 34A, 34B, 34C, 34D, 34E, 34F, 34G, 34H, 34I, 34J, 34K, 34L, 34M, 34N, 34O, and 34P becomes equal.

The connection relationship as in groups GR0 and GR1 explained above is also applied to other string units SU. As a result, in the semiconductor memory 1 of the second embodiment, the number of memory pillars MP connected to each bit line BL becomes equal.

Since the other configurations of the semiconductor memory 1 of the second embodiment are the same as those of the semiconductor memory 1 of the first embodiment, explanations thereof will be omitted.

[2-2] Advantageous Effects of Second Embodiment

In the above manner, in the semiconductor memory 1 of the second embodiment, the number of memory pillars MP connected to each bit line BL is made uniform.

As a result, in the semiconductor memory 1 of the second embodiment, characteristic variability for each bit line BL is further suppressed than in the first embodiment. Accordingly, the semiconductor memory 1 of the second embodiment is capable of suppressing errors caused by characteristic variability of the bit lines BL in various operations, and is capable of suppressing reduction in an operation speed of the semiconductor memory 1.

The semiconductor memory 1 of the second embodiment is capable of executing each of the read operation, the write operation, and the erase operation in the same manner as in the first embodiment. The semiconductor memory 1 of the second embodiment is able to obtain the same advantageous effects as in the first embodiment.

[2-3] Modified Example of Second Embodiment

In the second embodiment, the replacement pillars RP in the memory region MR of the memory cell array 10 may be arranged otherwise.

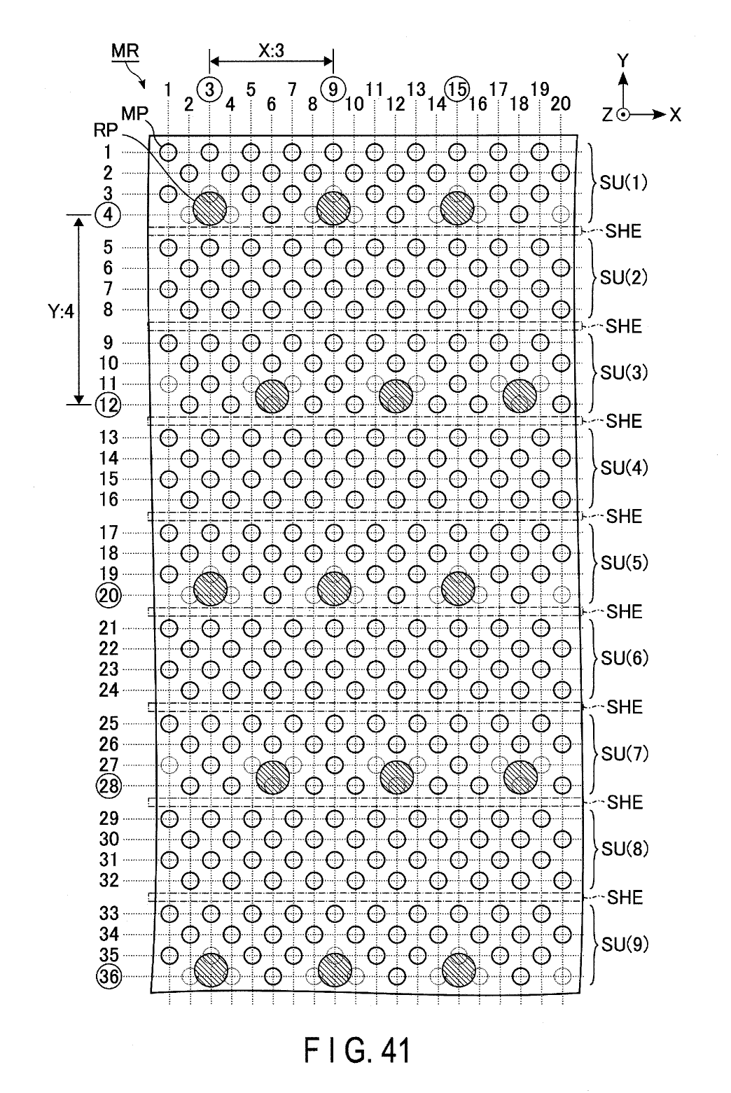

FIG. 41 to FIG. 44 each show an example of a plan layout of a memory cell array 10 in first to fourth modified examples of the second embodiment, and extract and show nine string units SU (1) to (9) that are arranged along the Y-direction in the memory cell array 10.

As in a first modified example of the second embodiment shown in FIG. 41, a plurality of replacement pillars RP may be arranged respectively at a position where the X-coordinate is “6×i+3” (i is an integer equal to or greater than 0) and the Y-coordinate is “16×j+4” (j is an integer equal to or greater than 0), and at a position where the X-coordinate is “6×i+6” and the Y-coordinate is “16×j+12”.

That is, in the first modified example of the second embodiment, an interval of the replacement pillars RP neighboring in the X-direction is the same as that in the second embodiment (FIG. 41, X:3). An interval of the replacement pillars RP neighboring in the Y-direction is the same as that in the second modified example of the first embodiment (FIG. 41, Y:4).

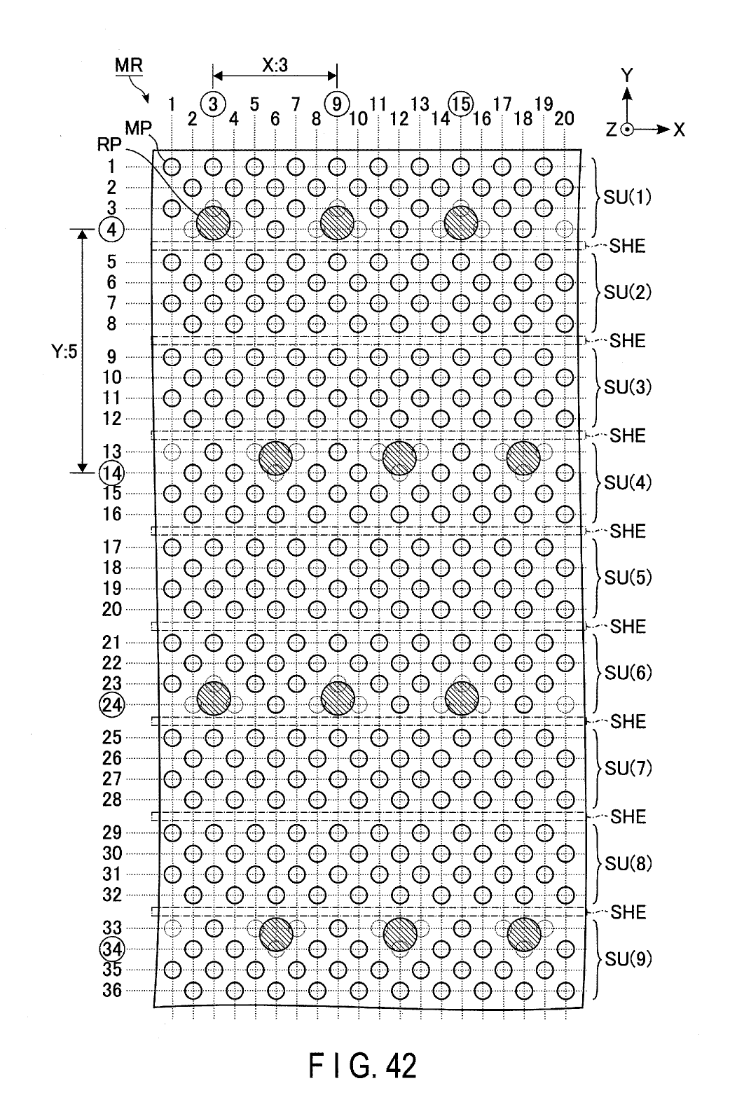

As in a second modified example of the second embodiment shown in FIG. 42, a plurality of replacement pillars RP may be arranged respectively at a position where the X-coordinate is “6×i+3” and the Y-coordinate is “20×j+4”, and at a position where the X-coordinate is “6×i+6” and the Y-coordinate is “20×j+14”.

That is, in the second modified example of the second embodiment, an interval of the replacement pillars RP neighboring in the X-direction is the same as that in the second embodiment (FIG. 42, X:3). An interval of the replacement pillars RP neighboring in the Y-direction is the same as that in the third modified example of the first embodiment (FIG. 42, Y:5).

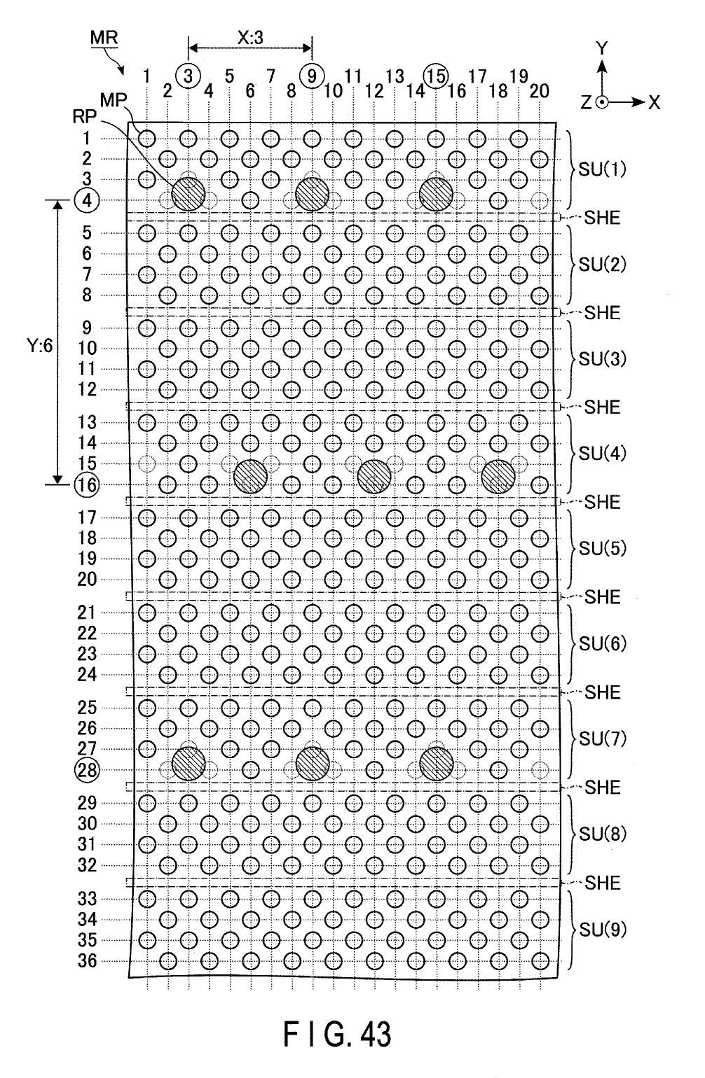

As in a third modified example of the second embodiment shown in FIG. 43, a plurality of replacement pillars RP may be arranged respectively at a position where the X-coordinate is “6×i+3” and the Y-coordinate is “24×j+4”, and at a position where the X-coordinate is “6×i+6” and the Y-coordinate is “24×j+16”.

That is, in the third modified example of the second embodiment, an interval of the replacement pillars RP neighboring in the X-direction is the same as that in the second embodiment (FIG. 43, X:3). An interval of the replacement pillars RP neighboring in the Y-direction is the same as that in the fourth modified example of the first embodiment (FIG. 43, Y:6).

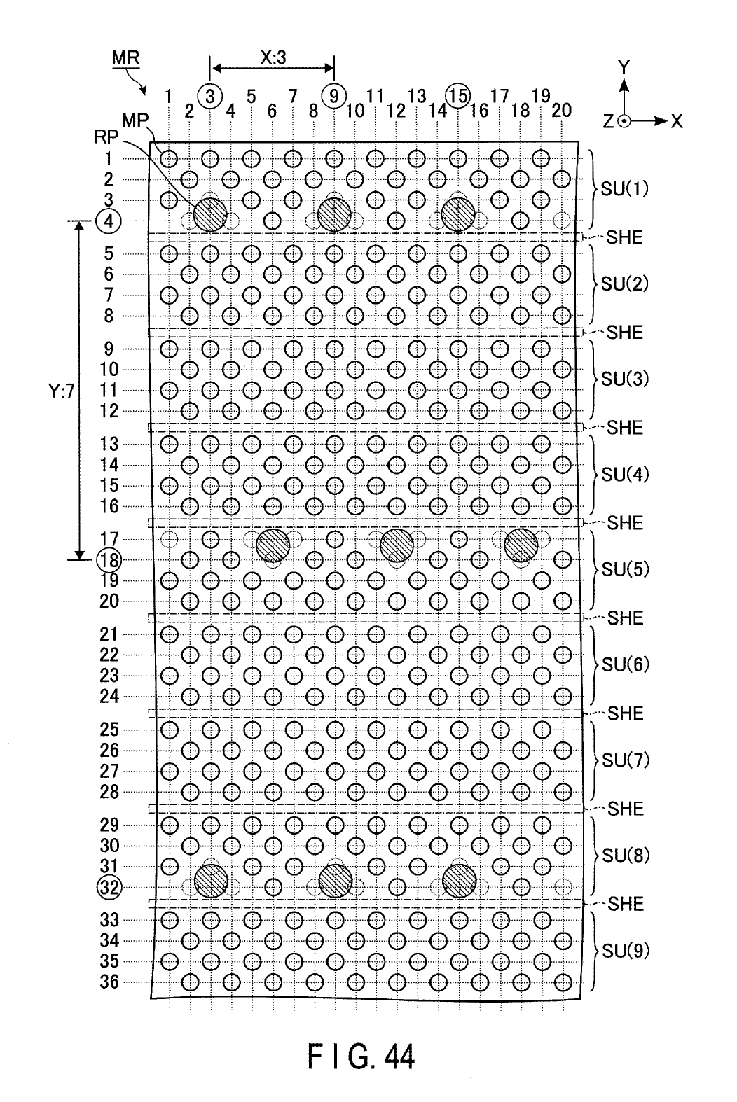

As in a fourth modified example of the second embodiment shown in FIG. 44, a plurality of replacement pillars RP may be arranged respectively at a position where the X-coordinate is “6×i+3” and the Y-coordinate is “28×j+4”, and at a position where the X-coordinate is “6×i+6” and the Y-coordinate is “28×j+18”.

That is, in the fourth modified example of the second embodiment, an interval of the replacement pillars RP neighboring in the X-direction is the same as that in the second embodiment (FIG. 44, X:3). An interval of the replacement pillars RP neighboring in the Y-direction is the same as that in the fifth modified example of the first embodiment (FIG. 44, Y:7).

The semiconductor memory 1 is able to obtain the same advantageous effects as in the second embodiment even in the case where any one of the first to fourth modified examples of the second embodiment explained above is adopted. Furthermore, the semiconductor memory 1 is able to obtain the same advantageous effects as in the second embodiment similar to the case where a connection method between the bit line BL and the memory pillar MP as explained using FIG. 40 is applied to the first modified example of the first embodiment.

### [3] Third Embodiment

A semiconductor memory 1 of a third embodiment has a configuration that permits an overlap of arrangements of a replacement pillar RP and a slit SHE in a plan layout of the memory cell array 10 explained in each of the first and the second embodiments. In the following, points that are different from the first and second embodiments regarding the semiconductor memory 1 according to the third embodiment will be explained.

[3-1] Plan Layout of Memory Cell Array 10

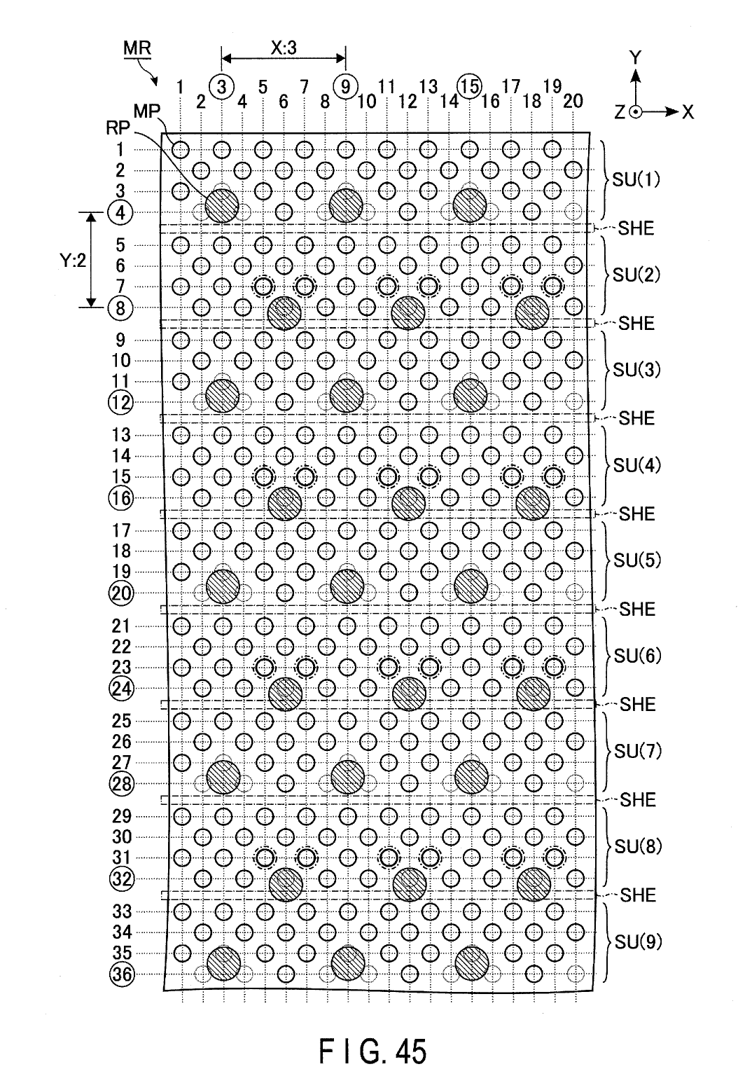

FIG. 45 shows an example of a plan layout of a memory cell array 10 in the third embodiment, and extracts and shows nine string units SU (1) to (9) that are arranged along the Y-direction in the memory cell array 10.

In an example shown in FIG. 45, in a similar coordinate as the second embodiment, a plurality of replacement pillars RP are arranged respectively at a position where the X-coordinate is “6×i+3” (i is an integer equal to or greater than 0) and the Y-coordinate is “8×j+4” (j is an integer equal to or greater than 0), and at a position where the X-coordinate is “6×i+6” and the Y-coordinate is “8×j+8”.

The plurality of replacement pillars RP in the third embodiment include replacement pillars RP that overlap with the arrangement of the slit SHE. Specifically, the plurality of pillars arranged at a position where the X-coordinate is “6×i+6” and the Y-coordinate is “8×j+8” are arranged so as to overlap the slit SHE.

Each of the memory pillars MP omitted in the semiconductor memory 1 of the second embodiment, such as the plurality of memory pillars MP arranged at a position where the X-coordinate is “6×i+5” and the Y-coordinate is “8×j+7”, and the plurality of memory pillars MP arranged at a position where the X-coordinate is “6×i+7” and the Y-coordinate is “8×j+7”, is provided in the semiconductor memory 1 of the third embodiment.

Since the other configurations of the semiconductor memory 1 of the third embodiment are the same as those of the semiconductor memory 1 of the first embodiment, explanations thereof will be omitted.

[3-2] Advantageous Effects of Third Embodiment

In the above manner, in the semiconductor memory 1 of the third embodiment, an overlap of the replacement pillar RP and the slit SHE is permitted.

As a result, in the semiconductor memory 1 of the third embodiment, the shift in the arrangement of the replacement pillars RP allows a memory pillar MP that could have not been formed in the first and second embodiments to be formed.

In the case of arranging the replacement pillars RP in similar coordinates, this allows the semiconductor memory 1 of the third embodiment to further increase a memory capacity of the memory cell array 10 than in either the first and second embodiments.

The semiconductor memory 1 of the third embodiment is capable of executing each of the read operation, the write operation, and the erase operation in the same manner as in the first embodiment. The semiconductor memory 1 of the third embodiment is able to obtain the same advantageous effects as in the first embodiment.

### [4] Other Modified Examples, Etc.

A semiconductor memory according to an embodiment includes first conductors, first pillars, a pillar column. The first conductors are stacked via an insulator. Each of the first pillars is provided through the first conductors. Each of the first pillars includes a portion intersecting one of the first conductors and functioning as a memory cell. The pillar column includes second pillars that are aligned in a first direction. Each of the second pillars is provided through the first conductors and does not include a portion functioning as the memory cell. The pillar column includes a first column of the second pillars and a second column of the second pillars. The first column of the second pillars and the second column of the second pillars are aligned in a second direction that intersects the first direction. The first pillars are arranged on both sides in the second direction of each of the first column and the second column. The first conductors are provided continuously on both sides in the second direction of the second pillars that are included in each of the first column and the second column. The first conductors are provided continuously in the second direction between the first column of the second pillars and the second column of the second pillars. Thus, a chip area of the semiconductor memory 1 can be reduced.

In the embodiments and the modified examples explained above, for example, the interval at which the replacement pillars RP are arranged becomes wider in the order of the first embodiment and the first to fifth modified examples of the first embodiment. In other words, the concentration of the plurality of replacement pillars RP provided in the memory region MR becomes lower in the order of the first embodiment and the first to fifth modified examples of the first embodiment.

Therefore, the number of memory pillars MP provided in the memory region MR increases in the order of, for example, the first embodiment and the first to fifth modified examples of the first embodiment. That is, in the case where the areas of the memory cell array 10 are assumed to be the same, the memory capacity of the semiconductor memory 1 increases in the order of, for example, the first embodiment and the first to fifth modified examples of the first embodiment.

Thus, in the semiconductor memory 1, as the number of replacement pillars RP decreases, the number of memory pillars MP to be omitted decreases, and the memory capacity per unit area of memory cell arrays 10 increases.

Accordingly, by designing the diameter and the arrangement of each of the memory pillars MP and the replacement pillars RP in a manner that the manufacturing method explained in [1-2] can be realized, the semiconductor memory 1 is able to increase the memory capacity per unit area. Therefore, in each of the embodiments and each of the modified examples explained above, the arrangements of the plurality of replacement pillars RP are preferred to be reduced as much as possible.

In the embodiments and the modified examples explained above, the number of NAND strings NS included in each of the string units SU may differ. That is, data capacity that can be stored in the cell unit CU may differ per string unit SU.

For example, the memory controller 2 instructs read and write of data for each cell unit CU to be executed in a certain page size to the semiconductor memory 1. Therefore, in some cases, a NAND string NS that would not be used may be included at the semiconductor memory 1.

The semiconductor memory 1 is capable of using such redundant NAND string NS as a redundant region.

Specifically, for example, when assuming a case in which a memory capacity of the cell unit CU in the first string unit SU is larger than that of the cell unit CU in the second string unit SU, and a malfunction has occurred at the memory pillar MP included in the first string unit SU, the semiconductor memory 1 can resolve the malfunction by using the redundant NAND string NS instead of the NAND string NS corresponding to the memory pillar MP at which the malfunction has occurred.

As a result, since the capacity of the NAND string NS that can resolve a malfunction can be increased, the semiconductor memory 1 is able to improve yield of the semiconductor memory 1.

In the first embodiment, the read operation, the write operation, and the erase operation of the semiconductor memory 1 have been explained; however, the voltage applied to the wiring of the word line WL, etc. when executing these operations may be estimated based on a voltage of a signal line between the driver module 14 and the row decoder module 15, or a signal line between the driver module 14 and the memory cell array 11.

In this specification, the term “connection” means electrical connection, and does not exclude a case in which, for example, the connection is made through another element. Furthermore, in this specification, the term “OFF-state” means applying to a corresponding transistor a voltage that is less than a threshold voltage of the transistor, and does not exclude a case in which, for example, a small amount of current such as a leak current of the transistor flows.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory comprising:
first conductors stacked via an insulator;
first pillars, each of the first pillars being provided through the first conductors, and each of the first pillars including a portion intersecting one of the first conductors and functioning as a memory cell; and
a pillar column including second pillars that are aligned in a first direction, each of the second pillars being provided through the first conductors and not including a portion functioning as the memory cell, wherein
the pillar column includes a first column of the second pillars and a second column of the second pillars, the first column of the second pillars and the second column of the second pillars being aligned in a second direction that intersects the first direction, and the first pillars being arranged on both sides in the second direction of each of the first column and the second column, and
the first conductors are provided continuously on both sides in the second direction of the second pillars that are included in each of the first column and the second column, and are provided continuously in the second direction between the first column of the second pillars and the second column of the second pillars.

2. The memory of claim 1, further comprising:
a second conductor connected to a bottom part of each of the first pillars and the second pillars of a first group among the first pillars and the second pillars; and
a third conductor connected to a bottom part of each of the first pillars and the second pillars of a second group among the first pillars and the second pillars.

3. The memory of claim 2, wherein
the bottom part of each of the second pillars of the first group is included in a layer on which the second conductor is provided, and
the bottom part of each of the second pillars of the second group is included in a layer on which the third conductor is provided.

4. The memory of claim 1, wherein a diameter of the second pillars is larger than a diameter of the first pillars.

5. The memory of claim 2, wherein
each of the first pillars includes a semiconductor that extends in an extending direction of the first pillar and an insulation film that surrounds an outer circumference of the semiconductor,
at each of the first pillars, the insulation film insulates between each of the semiconductor and the first conductors,
at each of the first pillars of the first group, each of the semiconductor and the second conductor come in contact via a side surface of each of the first pillars, and
at each of the first pillars of the second group, each of the semiconductor and the third conductor come in contact via a side surface of each of the first pillars.

6. The memory of claim 2, wherein
each of the second conductor and the third conductor has convex portions on a surface of the first conductor side,
each of the second pillars of the first group includes one of the convex portions of the second conductor, and
each of the second pillars of the second group includes one of the convex portions of the third conductor.

7. The memory of claim 2, further comprising:
a fourth conductor stacked via an insulator on a first conductor that is most distant from the second conductor among the first conductors; and
third pillars through the fourth conductor, each of the third pillars including a portion intersecting the fourth conductor and functioning as a first selection transistor, and the third pillars each being electrically connected to a part of the first pillars of the first group.

8. The memory of claim 7, further comprising:
a fifth conductor formed on a same wiring layer as the fourth conductor and adjacent to the fourth conductor, and divided from the fourth conductor by a first slit; and
fourth pillars through the fifth conductor, each of the fourth pillars including a portion intersecting the fifth conductor and functioning as a second selection transistor, and the fourth pillars each being electrically connected to a part of the first pillars of the second group, wherein
the second conductor and the third conductor are adjacent to each other on a same wiring layer, and the second conductor and the third conductor are divided by a second slit, and
an arrangement of the first slit includes a portion that overlaps an arrangement of the second slit along a direction in which the first conductors are stacked.

9. The memory of claim 2, wherein
the second conductor and the third conductor are aligned in the second direction, and
in a region on which the first pillars of the first group and the first pillars of the second group are formed, the first conductors have no portion that is divided by a slit extending in the first direction.

10. The memory of claim 8, wherein the second pillars include a second pillar that overlaps the first slit in a plane view.

11. The memory of claim 2, further comprising:
first and second bit lines, each of the first and second bit lines extending in the second direction, and being aligned in the first direction, wherein
the number of first pillars electrically connected to the first bit line among the first pillars of the first group differs from the number of first pillars electrically connected to the second bit line among the first pillars of the first group.

12. The memory of claim 1, further comprising:
bit lines, each of the bit lines extending in the second direction, and being aligned in the first direction, wherein
wider regions are formed in peripheries of the second pillars where an interval of the first pillars neighboring in the first direction and the second direction is larger than an interval of the first pillars neighboring in the first direction and the second direction in a region where the second pillars are not arranged, and
in a plane view, each of the bit lines is arranged to overlap at least one of the wider regions, and the number of first pillars electrically connected to each of the bit lines is equal.

13. The memory of claim 1, wherein an interval of the second pillars neighboring in the first direction among the second pillars is wider than an interval of two first pillars neighboring in the first direction among the first pillars.

14. The memory of claim 1, wherein an interval of the second pillars neighboring in the second direction among the second pillars is wider than an interval of two first pillars neighboring in the second direction among the first pillars.

15. A semiconductor memory comprising:
first and second memory cells;
a bit line connected to each of an end of the first memory cell and an end of the second memory cell;
a word line connected to each of a gate of the first memory cell and a gate of the second memory cell;
a first source line connected to another end of the first memory cell; and
a second source line that is different from the first source line connected to another end of the second memory cell.

16. The memory of claim 15, further comprising:
a first source selection transistor connected between the first memory cell and the first source line;
a second source selection transistor connected between the second memory cell and the second source line;
a first selection gate line connected to each of a gate of the first source selection transistor and a gate of the second source selection transistor; and
a controller that executes an erase operation, wherein
when performing the erase operation selecting the first memory cell, the controller:
applies a first voltage to the word line;
applies a second voltage that is higher than the first voltage to the first selection gate line;
applies a third voltage that is higher than the second voltage to the first source line; and
applies the second voltage to the second source line.

17. The memory of claim 16, further comprising:
a first drain selection transistor connected between the first memory cell and the bit line;
a second drain selection transistor connected between the second memory cell and the bit line;
a second selection gate line connected to a gate of the first drain selection transistor; and
a third selection gate line connected to a gate of the second drain selection transistor, wherein
when performing the erase operation selecting the first memory cell, the controller:
applies a fourth voltage that is between the first voltage and the third voltage to the second selection gate line, and
sets the third selection gate line in a floating state.

18. A method of manufacturing a semiconductor memory, comprising:
forming an underlying layer;
forming a stacked portion in which a first replacement member and a first insulator are alternately stacked above the underlying layer;
forming first holes and second holes in a manner that the first and second holes each penetrate the stacked portion, and in which a bottom part of each is included in the underlying layer;
after forming the first holes and the second holes, forming in the first holes a semiconductor and an insulation film surrounding an outer circumference of the semiconductor; and
after forming the semiconductor and the insulation film in the first holes, removing the first replacement member via the second holes, and forming a first conductor in a space where the first replacement member was provided.

19. The method of claim 18, further comprising:
prior to forming the stacked portion, forming a slit for dividing the underlying layer, each of the divided underlying layers being in contact with at least one of the second holes that are formed subsequently.

20. The method of claim 18, wherein the underlying layer includes a second replacement member,
the method further comprising, after forming the semiconductor and the insulation film in the first holes, removing the second replacement member via the second holes prior to removing the first replacement member, and forming a second conductor in a space where the second replacement member was provided.
